(19) United States
(12) Patent Application Publication
(10) Pub. No.: US 2025/0062235 A1
(43) Pub. Date: Feb. 20, 2025

(54) PACKAGE SUBSTRATE WITH METALLIZATION LAYER(S) THAT INCLUDES AN ADDITIONAL METAL PAD LAYER TO FACILITATE REDUCED VIA SIZE FOR REDUCED BUMP PITCH, AND RELATED INTEGRATED CIRCUIT (IC) PACKAGES AND FABRICATION METHODS

(71) Applicant: QUALCOMM Incorporated, San Diego, CA (US)

(72) Inventors: Joan Rey Villarba Buot, Escondido, CA (US); Hong Bok We, San Diego, CA (US); Zhijie Wang, San Diego, CA (US); Sang-Jae Lee, San Diego, CA (US)

(21) Appl. No.: 18/450,636

(22) Filed: Aug. 16, 2023

(51) Int. Cl. H01L 23/538; H01L 21/48; H01L 25/16

(52) U.S. Cl. CPC H01L 23/5383; H01L 21/4857; H01L 25/16

(57) ABSTRACT

Package substrate with metallization layer(s) that includes an additional metal pad layer to facilitate reduced via size for reduced bump pitch, and related integrated circuit (IC) packages and fabrication methods. An additional metal pad(s) is provided in an insulating layer of a metallization layer(s) of the package substrate in which a via(s) is formed to reduce vertical connectivity distance between metal interconnects in adjacent metallization layers electrically coupled together by the via. This can reduce the aspect ratio and size of the via thereby allowing metal interconnects that are electrically coupled to the via to also be reduced in size (e.g., width) while still supporting an aligned, low resistance connection between the via(s) and the metal interconnects. Being able to reduce the size (e.g., width) of the metal interconnects can reduce bump pitch of the package substrate, which can facilitate a higher density of die/bump connections to the package substrate.

### BACKGROUND

### I. Field of the Disclosure

The field of the disclosure relates to integrated circuit (IC) packages, and more particularly to design and fabrication of package substrates that support signal routing to a semiconductor die(s) in the IC package.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The package substrate includes one or more metallization layers that include metal interconnects (e.g., metal traces, metal lines) with vias coupling the metal interconnects together between adjacent metallization layers to provide electrical interfaces between the die(s). The die(s) is electrically interfaced to metal interconnects exposed in a top or outer metallization layer of the package substrate to electrically couple the die(s) to the metal interconnects of the package substrate. For example, the package substrate may include an embedded trace substrate (ETS) layer adjacent to the die to facilitate higher density bump/solder joints for coupling the die(s) to the package substrate. Metal interconnects in the outer metallization layer are coupled to other metal interconnects in other, lower metallization layers in the package substrate to provide signal routing paths to a coupled die. For example, a package substrate may be a semi-additive process (SAP) substrate or an ETS.

It is common to include a capacitor(s) in an IC package. As one example, a capacitor may be provided in an IC package and coupled to power and ground in a power distribution network (PDN) in the IC package to provide a decoupling capacitance in the PDN. The decoupling capacitance can shunt noise from one electrical circuit (e.g., a power supply circuit) to another electrical circuit (e.g., a powered electrical circuit). Reducing noise in a PDN may be particularly important for die applications that are particularly sensitive to noise, such as a die that includes a high-speed communication interface. As another example, a capacitor may also be provided in an IC package to provide part of a filtering circuit in the die of the IC package. A capacitor can be provided in an IC package as a land-side capacitor (LSC) that is coupled to the package substrate on an opposite side from a die coupled to the package substrate. The capacitor may also be provided as a deep trench capacitor (DTC) for its known benefit of reduced inductance. A DTC is formed similar to a semiconductor device, and thus can be coupled to a package substrate through metal bumps like a die. Metal interconnects/metal traces within metallization layers of the package substrate can be used to provide an electrical connection between a die and the capacitor.

PDN performance in an IC package can be improved by minimizing the inductance in the PDN. Reduced inductance in a PDN can result in faster charge and discharge times, reduced voltage droop and energy losses, and electro-magnetic interference (EMI) reduction in the PDN. One way to reduce inductance in a PDN of an IC package is to reduce the inductance loop by reducing the connection path length between the capacitor and the die. For a land-side DTC in an IC package, if the metallization layers of the package substrate can be fabricated to support a bump pitch that matches the interconnection pitch of both the DTC and the die, the connection between the DTC and the die can be provided as a direct via stack connection in the package substrate to minimize the inductance loop. A direct via stack connection is a connection path provided as a series of via and metal interconnect connections that are aligned in a vertical direction of the package substrate from one side of the package substrate to its other, opposite side. The capacitance provided by the DTC can also be increased to increase performance of the PDN by increasing the number of power and ground connections between the DTC and the die through the package substrate. However, providing an increased number power and ground connections between the DTC and the die may require a bump pitch reduction in the package substrate that may not be possible due to limitations in package fabrication processes and associated design rules.

### SUMMARY OF THE DISCLOSURE

Aspects disclosed herein include a package substrate with a metallization layer(s) that includes an additional metal pad layer to facilitate reduced via size for reduced bump pitch. Related integrated circuit (IC) packages and fabrication methods are also disclosed. The additional metal pad layer is a metal pad layer provided in an insulating layer of a metallization layer that is in addition to a metal layer with metal interconnects in the metallization layer. Providing the additional metal pad layer in a metallization layer decreases the depth in which a via(s) is formed in a metallization layer, thereby reducing the aspect ratio and size (i.e., width or diameter) of the via. Reducing via size in a metallization layer of the package substrate allows a metal interconnect that provides a connection pad for the via to also be reduced in size (e.g., width) while still supporting an aligned, low resistance connection between the vias and the metallization interconnects. In turn, being able to reduce the size (e.g., width) of metal interconnects in the package substrate can reduce the bump pitch of the package substrate, which can facilitate a higher density of die/bump connections to the package substrate. Reducing the bump pitch of the package substrate can also facilitate other benefits like an improved power distribution network (PDN) in the IC package. As an example, if the IC package includes a deep trench capacitor (DTC) coupled to a die through the package substrate, the reduced bump pitch of the package substrate may facilitate multiple, additional power and ground connections between the capacitor and the die to improve the decoupling capacitance provided by the DTC in the PDN.

In this regard, the package substrate includes a plurality of metallization layers that each include a metal layer in which metal interconnects are formed. Metallization layers in the package substrate also include vias that interconnect metal interconnects in adjacent metallization layers to provide signal routing paths in the package substrate. For example, an IC package may include a die coupled to a first, die side of the package substrate that is electrically coupled to a capacitor coupled to a land side of the package substrate through electrical connection paths provided by metal interconnects interconnected by vias in the metallization layers in the package substrate. The vias are formed in alignment with the metal interconnects in which they are coupled to provide a low resistance interconnection between the vias and metal interconnects. Thus, the size (e.g., width) of a via-connected metal interconnect should be sufficiently sized to allow for the aligned formation of a via coupled to the metal interconnect. For example, the vias may be formed by drilling an opening into a metallization layer down to a metal interconnect and then filling in the opening with a metal material. However, a larger vertical distance between metal interconnects in adjacent metallization layers of the package substrate results in a larger aspect ratio of the vias, and thus a larger vias size (i.e., width or diameter). This may then cause the metal interconnects in the metallization layers to be larger in size to reliably achieve an aligned, low resistance via connection. Reducing the widths of the metallization layers of the package substrate to reduce the aspect ratio and thus size of the vias may not be possible due to process or other limitations. Because the size (e.g., width) of the metal interconnects drives the bump pitch of the package substrate, reducing the size (e.g., width) of the metal interconnects in the package substrate may require a reduced via size.

Thus, in exemplary aspects, an additional metal pad layer is provided in an insulating layer of a metallization layer(s) of the package substrate in which a first via(s) is formed. The additional metal pad layer includes an additional metal pad(s) that is coupled to a first metal interconnect(s) in a first metal layer in a first metallization layer. Thus, the additional metal pad(s) decreases the vertical connectivity distance between the first metal interconnect(s) and second metal interconnect(s) in an adjacent, second metallization layer that is coupled to the first metal interconnect(s) through the first via(s). In this manner, the first via(s) only has to be formed in the first metallization layer to a shorter depth down only to the additional metal pad(s) in the first metallization layer, which in turn reduces the aspect ratio and size (i.e., diameter, width) of the first via(s). In this manner, the first metal interconnect(s) can be reduced in width while still providing a reliable, aligned connection to the first via(s) through the additional metal pad(s), thus allowing for a reduced metal interconnect pitch in the package substrate. A reduced metal interconnect pitch in the package substrate allows for a reduced bump pitch of the package substrate.

In another exemplary aspect, the package substrate is an embedded trace substrate (ETS) that includes a metallization layer(s) with an insulating layer and an adjacent metal layer with an embedded metal trace(s) embedded in the insulating layer. The insulating layer of the metallization layer(s) includes an additional metal pad layer that includes an additional metal pad(s) formed in contact with an embedded metal trace(s). A via(s) is formed in contact with an additional metal pad(s) to provide an electrical connection between the via(s) and the embedded metal trace(s) in the metal layer. The additional metal pad reduces the vertical distance in which the via(s) is formed to provide an electrical connection to the embedded metal trace(s), thereby allowing the via(s) to be formed of a reduced size due to a lower aspect ratio. The reduced via(s) size in turn allows the additional metal pad(s) to be reduced in width while still providing an aligned and reliable low resistance connection to the via(s), which in turn allows the embedded metal trace(s) to be reduced in width supporting a lower bump pitch for the package substrate.

In another exemplary aspect, the package substrate is a semi-additive process (SAP) substrate that includes a metallization layer(s) with an insulating layer and an adjacent metal layer that includes a metal interconnect(s). The insulating layer of the metallization layer(s) includes an additional metal pad layer that includes an additional metal pad(s) formed in contact with a metal interconnect(s) in the metal layer. A via(s) is formed in contact with an additional metal pad(s) to provide an electrical connection between the via(s) and a metal interconnect(s) in the metal layer. The additional metal pad(s) reduces the vertical distance in which the via(s) is formed to provide an electrical connection to the metal interconnect(s), thereby allowing the via(s) to be formed of a reduced size due to a lower aspect ratio. The reduced via size in turn allows the additional metal pad(s) to be reduced in width while still providing an aligned and reliable low resistance connection to the via(s), which in turn allows the metal interconnect(s) to be reduced in width supporting a lower bump pitch for the package substrate.

In this regard, in one exemplary aspect, a package substrate is provided. The package substrate comprises a first metallization layer extending in a first direction. The first metallization layer comprises a first surface and a second surface opposite the first surface in a second direction orthogonal to the first direction. The first metallization layer also comprises a first metal layer adjacent to the first surface, the first metal layer, comprising a plurality of first metal interconnects. The first metallization layer also comprises a first insulating layer comprising a first metal pad layer. The first metal pad layer comprises a plurality of first metal pads each in contact with a first metal interconnect of the plurality of first metal interconnects, and a plurality of first vias adjacent to the second surface and each in contact with a first metal pad of the plurality of first metal pads.

In another exemplary aspect, a method of fabricating a package substrate is provided. The method comprises forming a first metallization layer extending in a first direction. The method of forming the first metallization layer comprises forming a first metal layer adjacent to a first surface. The method of forming the first metallization layer also comprises forming a plurality of first metal interconnects in the first metal layer. The method of forming the first metallization layer also comprises forming a first metal pad layer adjacent to the first metal layer. The method of forming the first metallization layer also comprises forming a plurality of first metal pads in the first metal pad layer and each in contact with a first metal interconnect of the plurality of first metal interconnects. The method of forming the first metallization layer also comprises disposing a first insulating layer on the plurality of first metal pads and the first surface adjacent to the plurality of first metal interconnects. The method of forming the first metallization layer also comprises forming a plurality of first vias in the first insulating layer and each in contact with a first metal pad of the plurality of first metal pads, the plurality of first vias adjacent to a second surface opposite the first surface in a second direction orthogonal to the first direction.

In another exemplary aspect, an IC package is provided. The IC package comprises a package substrate. The package substrate comprises a first metallization layer extending in a first direction, the first metallization layer comprising a first surface and a second surface opposite the first surface in a second direction orthogonal to the first direction, a first metal layer adjacent to the first surface, the first metal layer comprising a plurality of first metal interconnects, and a first insulating layer. The first insulating layer comprises a first metal pad layer, comprising: a plurality of first metal pads each in contact with a first metal interconnect of the plurality of first metal interconnects, and a plurality of first vias adjacent to the second surface and each in contact with a first metal pad of the plurality of first metal pads. The IC package also comprises a die comprising a plurality of die interconnects each coupled to a first metal interconnect of the plurality of first metal interconnects.

### BRIEF DESCRIPTION OF THE FIGURES

FIG. 1 is a side view of an integrated circuit (IC) package that includes a semiconductor die (“die”) coupled to a package substrate in the form of an embedded trace substrate (ETS), wherein the ETS includes ETS metallization layers that include embedded metal traces connected by vias to provide signal routing paths in the ETS;

FIG. 2A is a side view of an exemplary IC package that includes a die coupled to an exemplary package substrate in the form of an ETS, wherein the ETS includes metallization layers that include a metal pad layer (additional metal pad layer) in an insulating layer of a metallization layer electrically coupling a via to a metal interconnect (e.g., an embedded metal trace) in a metal layer of the metallization layers to facilitate a reduced via size and metal interconnect size to support a reduced bump pitch in the package substrate;

FIG. 2B is a close-up side view of the ETS in the IC package in FIG. 2A;

FIG. 3A is a side view of exemplary metallization layers of the ETS in FIGS. 2A and 2B illustrating metal interconnects interconnected through vias coupled to additional metal pads formed in an additional metal pad layer of an insulating layer of metallization layers;

FIG. 3B is a side view of other exemplary metallization layers of the ETS in FIGS. 2A and 2B illustrating metal interconnects interconnected through vias coupled to additional metal pads formed in an additional metal pad layer of an insulating layer of metallization layers, and with laterally intervening metal interconnects not coupled together with vias

FIG. 4A is a side view of exemplary metallization layers of an ETS illustrating metal interconnects interconnected through vias without additional metal pads;

FIG. 4B is a side view of exemplary metallization layers of an ETS illustrating metal interconnects interconnected through vias without additional metal pads, and with laterally intervening metal interconnects not coupled together with vias;

FIG. 5 is a flowchart illustrating an exemplary fabrication process of fabricating a package substrate that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate, including, but not limited to, the ETSs in FIGS. 2A-3B;

FIGS. 6A-6D is a flowchart illustrating another exemplary fabrication process of fabricating a package substrate in the form of an ETS that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate, including, but not limited to, the ETSs in FIGS. 2A-3B;

FIGS. 7A-7I are exemplary fabrication stages during fabrication of an ETS according to the fabrication process in FIGS. 6A-6D;

FIG. 8 is a side view of another exemplary package substrate in the form of a semi-additive process (SAP) substrate, wherein the SAP substrate includes metallization layers that include a metal pad layer (additional metal pad layer) in an insulating layer of a metallization layer electrically coupling a via to a metal interconnect (e.g., an embedded metal trace) in a metal layer of the metallization layers to facilitate a reduced via size and metal interconnect size to support a reduced bump pitch in the package substrate;

FIG. 9A is a side view of exemplary metallization layers of the SAP substrate in FIG. 8 illustrating metal interconnects interconnected through vias coupled to additional metal pads formed in an additional metal pad layer of an insulating layer of metallization layers;

FIG. 9B is a side view of other exemplary metallization layers of the SAP substrate in FIG. 8 illustrating metal interconnects interconnected through vias coupled to additional metal pads formed in an additional metal pad layer of an insulating layer of a metallization layer, and with laterally intervening metal interconnects not coupled together with vias

FIG. 10A is a side view of exemplary metallization layers of a SAP substrate illustrating metal interconnects interconnected through vias without additional metal pads;

FIG. 10B is a side view of exemplary metallization layers of a SAP substrate illustrating metal interconnects interconnected through vias without additional metal pads, and with laterally intervening metal interconnects not coupled together with vias;

FIGS. 11A-11C is a flowchart illustrating another exemplary fabrication process of fabricating package substrate in the form of a SAP substrate that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate, including, but not limited to, the SAP substrates in FIGS. 8-9B;

FIGS. 12A-12I are exemplary fabrication stages during fabrication of the SAP substrate according to the fabrication process in FIGS. 11A-11C; and

FIG. 13 is a block diagram of an exemplary wireless communications device that includes radio-frequency (RF) components that can include an IC package(s) that includes a die coupled to an exemplary package substrate, wherein the package substrate includes metallization layers that include an additional metal pad layer in an insulating layer of a metallization layer electrically coupling a via to a metal interconnect (e.g., an embedded metal trace) in a metal layer of the metallization layers to facilitate a reduced via size and metal interconnect size to support a reduced bump pitch in the package substrate, including, but not limited to, the package substrates in FIGS. 2A-3B, 7I, 8-9B, and 12I, and according to the exemplary fabrication processes in FIGS. 5, 6A-6D, and 11A-11C;

FIG. 14 is a block diagram of an exemplary processor-based system that can include components that can include an IC package(s) that includes a die coupled to an exemplary package substrate, wherein the package substrate includes metallization layers that include an additional metal pad layer in an insulating layer of a metallization layer electrically coupling a via to a metal interconnect (e.g., an embedded metal trace) in a metal layer of the metallization layers to facilitate a reduced via size and metal interconnect size to support a reduced bump pitch in the package substrate, including, but not limited to, the package substrates in FIGS. 2A-3B, 7I, 8-9B, and 12I, and according to the exemplary fabrication processes in FIGS. 5, 6A-6D, and 11A-11C

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a package substrate with a metallization layer(s) that includes an additional metal pad layer to facilitate reduced via size for reduced bump pitch. Related integrated circuit (IC) packages and fabrication methods are also disclosed. The additional metal pad layer is a metal pad layer provided in an insulating layer of a metallization layer that is in addition to a metal layer with metal interconnects in the metallization layer. Providing the additional metal pad layer in a metallization layer decreases the depth in which a via(s) is formed in a metallization layer, thereby reducing the aspect ratio and size (i.e., width or diameter) of the via. Reducing via size in a metallization layer of the package substrate allows a metal interconnect that provides a connection pad for the via to also be reduced in size (e.g., width) while still supporting an aligned, low resistance connection between the vias and the metallization interconnects. In turn, being able to reduce the size (e.g., width) of metal interconnects in the package substrate can reduce the bump pitch of the package substrate, which can facilitate a higher density of die/bump connections to the package substrate. Reducing the bump pitch of the package substrate can also facilitate other benefits like an improved power distribution network (PDN) in the IC package. As an example, if the IC package includes a deep trench capacitor (DTC) coupled to a die through the package substrate, the reduced bump pitch of the package substrate may facilitate multiple, additional power and ground connections between the capacitor and the die to improve the decoupling capacitance provided by the DTC in the PDN.

In this regard, the package substrate includes a plurality of metallization layers that each include a metal layer in which metal interconnects are formed. Metallization layers in the package substrate also include vias that interconnect metal interconnects in adjacent metallization layers to provide signal routing paths in the package substrate. For example, an IC package may include a die coupled to a first, die side of the package substrate that is electrically coupled to a capacitor coupled to a land side of the package substrate through electrical connection paths provided by metal interconnects interconnected by vias in the metallization layers in the package substrate. The vias are formed in alignment with the metal interconnects in which they are coupled to provide a low resistance interconnection between the vias and metal interconnects. Thus, the size (e.g., width) of a via-connected metal interconnect should be sufficiently sized to allow for the aligned formation of a via coupled to the metal interconnect. For example, the vias may be formed by drilling an opening into a metallization layer down to a metal interconnect and then filling in the opening with a metal material. However, a larger vertical distance between metal interconnects in adjacent metallization layers of the package substrate results in a larger aspect ratio of the vias, and thus a larger vias size (i.e., width or diameter). This may then cause the metal interconnects in the metallization layers to be larger in size to reliably achieve an aligned, low resistance via connection. Reducing the widths of the metallization layers of the package substrate to reduce the aspect ratio and thus size of the vias may not be possible due to process or other limitations. Because the size (e.g., width) of the metal interconnects drives the bump pitch of the package substrate, reducing the size (e.g., width) of the metal interconnects in the package substrate may require a reduced via size.

Thus, in exemplary aspects, an additional metal pad layer is provided in an insulating layer of a metallization layer(s) of the package substrate in which a first via(s) is formed. The additional metal pad layer includes an additional metal pad(s) that is coupled to a first metal interconnect(s) in a first metal layer in a first metallization layer. Thus, the additional metal pad(s) decreases the vertical connectivity distance between the first metal interconnect(s) and second metal interconnect(s) in an adjacent, second metallization layer that is coupled to the first metal interconnect(s) through the first via(s). In this manner, the first via(s) only has to be formed in the first metallization layer to a shorter depth down only to the additional metal pad(s) in the first metallization layer, which in turn reduces the aspect ratio and size (i.e., diameter, width) of the first via(s). In this manner, the first metal interconnect(s) can be reduced in width while still providing a reliable, aligned connection to the first via(s) through the additional metal pad(s), thus allowing for a reduced metal interconnect pitch in the package substrate. A reduced metal interconnect pitch in the package substrate allows for a reduced bump pitch of the package substrate.

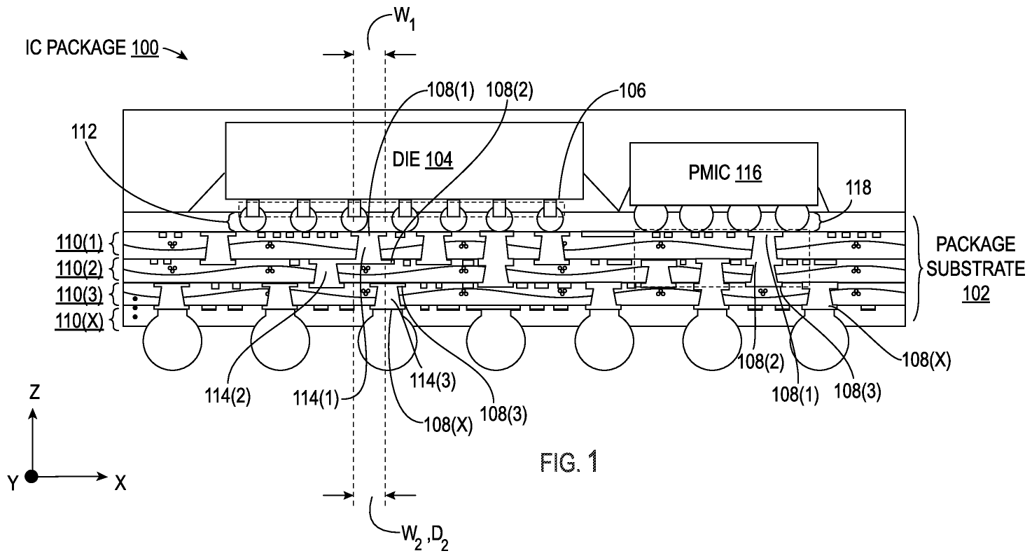

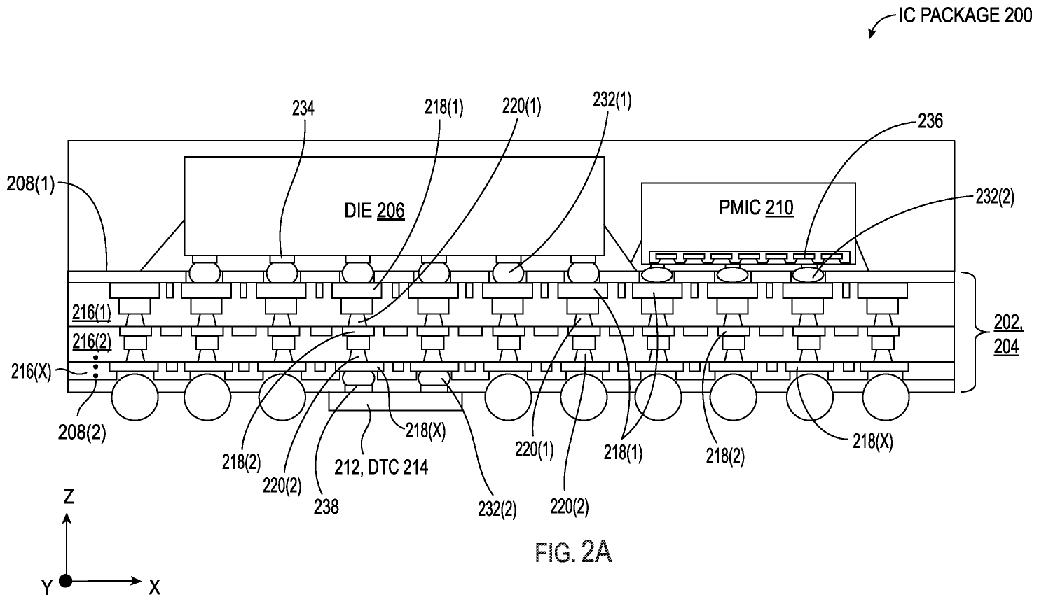

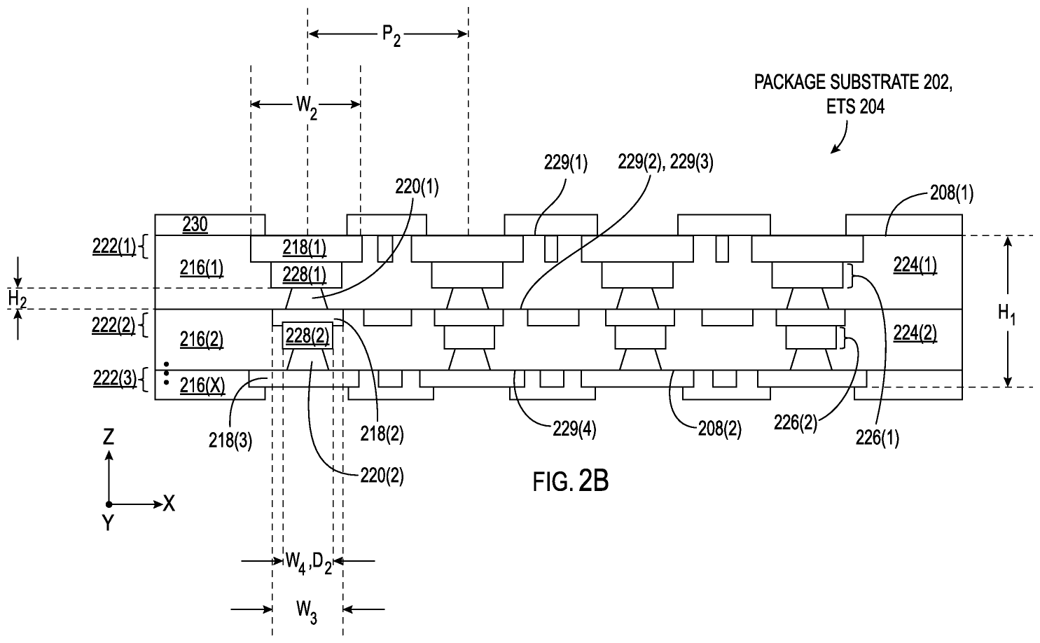

Before discussing examples of package substrates for IC packages that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate, starting at FIG. 2A, FIG. 1 is provided. FIG. 1 is a side view of an integrated circuit (IC) package 100 that include a package substrate 102 that does not include an additional metal pad layer in an insulating layer to facilitate a reduced via size and metal interconnect size to support a reduced bump pitch in the package substrate 102.

In this regard, as shown in FIG. 1, the IC package 100 includes a semiconductor die (“die”) 104 coupled to the package substrate 102 through die interconnects 106 (e.g., metal pads) coupled to metal interconnects 108(1) (e.g., metal traces, metal lines) in an outer metallization layer 110(1) of the package substrate 102. The metal interconnects 108(1) of the outer metallization layer 110(1) are coupled to the die interconnects 106 through external metal bumps 112 (e.g., solder bumps, solder joints, ball grid array (BGA) interconnects, micro-bumps). The bump pitch P₁ of the metal bumps 112 drives die interconnect 106 pitch of the die 104. The package substrate 102 in this example also includes additional metallization layers 110(2)-110(X) that each have respective metal interconnects 108(2)-108(X) (e.g., metal traces, metal lines) interconnected by respective vias 114(1)-114(3) (e.g., metal posts). The metallization layers 110(1)-110(X) extend in a first, horizontal direction(s) (X-axis and/or Y-axis direction(s)). In this manner, signals can be routed in the first, horizontal direction (X-axis and/or Y-axis direction(s)).and a second, vertical direction (Z-axis direction) orthogonal to the first direction, between the die 104 and metal interconnects 108(1)-108(X) coupled by vias 114(1)-114(3) in the metallization layers 110(1)-110(X) in the package substrate 102.

With continuing reference to FIG. 1, another semiconductor device 116 in the form of a power management IC (PMIC) 116 in this example is also coupled to the outer metallization layer 110(1) of the package substrate 102. The PMIC 116 manages the supply of power to the die 104. The PMIC 116 is coupled to metal interconnects 108(1) (e.g., metal traces, metal lines) in the outer metallization layer 110(1) through external metal bumps 118 (e.g., solder bumps, solder joints, BGA interconnects) coupled to the PMIC 116. In this manner, signals can be routed to the die 104 through signal routing between the metal interconnects 108(1)-108(X) coupled by the vias 114(1)-114(3) in the metallization layers 110(1)-110(X) in the package substrate 102.

In the example IC package 100 in FIG. 1, the package substrate 102 is an embedded trace substrate (ETS), wherein the metal interconnects 108(1)-108(X) are provided as embedded metal traces. An ETS can support providing a higher density of embedded metal traces with a reduced line/spacing ratio (L/S) to support higher density I/O connections.

With continuing reference to FIG. 1, the vias 114(1)-114(X) in the metallization layers 110(1) 110(X) can be formed in alignment in the second, vertical direction (Z-axis direction) with coupled metal interconnects 108(1)-108(X) to provide a low resistance interconnection between the vias 114(1)-114(X) and coupled metal interconnects 108(1)-108(X). Thus, the size (e.g., width W₁) of a via-connected metal interconnect 108(1)-108(X) should be sufficiently sized to allow for the aligned formation of a via 114(1)-114(X) coupled to the metal interconnect 108(1)-108(X). For example, the vias 114(1)-114(X) may be formed by drilling an opening into a respective metallization layer 110(1)-110(X) from a bottom side of the metallization layer 110(1)-110(X) down to a respective metal interconnect 108(1)-108(X) and then filling in the opening with a metal material. However, the vertical distance between metal interconnects 108(1)-108(X) in adjacent metallization layers 110(1)-110(X) of the package substrate 102 in the second, vertical direction (Z-axis direction) results in a larger aspect ratio of the vias 114(1)-114(X), and thus vias 114(1)-114(X) of a larger size (i.e., width W₂ or diameter D₂). Thus, the size (e.g., width W₁) of a via-connected metal interconnect 108(1)-108(X) must also be sized sufficiently large to support an aligned, low-resistance connection to a coupled via 114(1)-114(X). However, since the size (e.g., width W₁) of a via-connected metal interconnect 108(1)-108(X) drives the bump pitch P₁ of the metal bumps 112, this may cause the bump pitch P₁ to be greater than desired to support a die 104 and/or PMIC 116 of a desired interconnect pitch. For example, it may be desired for the package substrate 102 to support a reduced die interconnect pitch for the die 104 to support a die 104 with a higher density of die interconnects.

The heights of the metallization layers 110(1)-110(X) in the second, vertical direction (Z-axis direction) could be reduced to reduce the aspect ratio and thus the size of the vias 114(1)-114(X). However, this may not be possible due to process or other limitations for the package substrate 102.

In this regard, to provide a package substrate from an IC package that can support a reduced bump pitch while also providing for low resistance connections between metal interconnects in the package substrate, an exemplary IC package 200 in FIGS. 2A and 2B is provided. FIG. 2A is a side view of the exemplary IC package 200 that includes a package substrate 202 in the form of an ETS 204 in this example. FIG. 2B is a close-up side view of the package substrate 202 in the IC package 200 in FIG. 2A. As shown in FIG. 2A, a die 206 is coupled to a first, die surface 208(1) of the ETS 204 as part of the IC package 200. In this example, a PMIC 210 that manages the supply of power to the die 206 is also coupled to the first, die surface 208(1) of the package substrate 202 as part of the IC package 200. In this example, a capacitor 212 is also coupled to the package substrate 202 as part of the IC package 200. For example, the capacitor 212 may be a deep trench capacitor (DTC) 214 that is provided in the form of a semiconductor type device and coupled to a second, land surface 208(2) of the package substrate 202.

As shown in FIG. 2A, the package substrate 202 includes one or more metallization layers 216(1)-216(X), wherein ‘X’ represents a whole positive integer of the number of metallization layers 216(1)-216(X) included. The metallization layers 216(1)-216(X) extend in a first, horizontal direction(s) (X-axis and/or Y-axis direction(s)). The PMIC 210 and DTC 214 are electrically coupled to the die 206 through the metallization layers 216(1)-216(X) in the package substrate 202. The die 206 is electrically coupled to the PMIC 210 through an electrical connection between the die 206 and the PMIC 210 to one or more metal interconnects 218(1)-218(X) in the upper, first metallization layer 216(1) and/or one or more other lower metallization layers 216(2)-216(X) of the package substrate 202. If the electrical coupling of the die 206 to the PMIC 210 involves signal routing through a lower metallization layer 216(2)-216(X), a first metal interconnect 218(1) coupled to the die 206 and a first metal interconnect 218(1) coupled to the PMIC 210 are also coupled to other adjacent metal interconnects 218(2)-218(X) through one or more respective first and second vias 220(1), 220(2) to provide a signal routing path(s) between the die 206 and the PMIC 210.

As also shown in FIG. 2A, the die 206 is also electrically coupled to the DTC 214, as a decoupling capacitor in this example, through an electrical connection between the die 206 and the DTC 214 in the metallization layers 216(1)-216(X) of the package substrate 202. In this example, since the die 206 and the DTC 214 are coupled to the respective opposite first, die surface 208(1) and the second, land surface 208(2) of the package substrate 202 in the second, vertical direction (Z-axis direction) orthogonal to the first, horizontal direction(s) (X-axis and/or Y-axis direction(s)), the electrical connection of the die 206 to the DTC 214 involves signal routing through each of the metallization layers 216(1)-216(X). Such signal routing involves metal interconnects 218(1)-218(X) electrically coupled together with intervening vias 220(1), 218(2). For example, as shown in FIG. 2A, the die 206 and the DTC 214 are electrically coupled together vertically in a via stack that involves vertically aligned metal interconnects 218(1)-218(X) in the second, vertical direction (Z-axis direction) interconnected by vias 220(1), 220(2) in a vertical path in the second, vertical direction (Z-axis direction) to minimize the connection path distance to minimize the inductance loop in the DTC 214.

As shown in the package substrate 202 in FIG. 2B, the size (e.g., width W₂) of the first metal interconnects 218(1) in the first, upper metallization layer 216(1) should be sufficiently sized to allow for the aligned formation of the first vias 220(1) to be electrically coupled to the first metal interconnect 218(1) with a low resistance connection, such as to the DTC 214 (see FIG. 2A). The size (e.g., width W₃) of the second metal interconnects 218(2) in the second metallization layer 216(2) should also be sufficiently sized to allow for the aligned formation of the second vias 220(2) to be electrically coupled to the second metal interconnect 218(1) with a low resistance connection, such as to the DTC 214 (see FIG. 2A). For example, the vias 220(1), 220(2) may be formed by drilling an opening into their respective metallization layers 216(1), 216(2) down to the respective metal interconnects 218(1), 218(2) as part of the fabrication of the metallization layers 216(1), 216(2) and then filling in the openings with a metal material. However, the vertical height H₁ between metal interconnects 218(1)-218(X) in adjacent metallization layers 216(1)-216(X) of the package substrate 202 could result in the vias 220(1), 220(2) in the metallization layers 216(1), 216(2) having a larger aspect ratio that then may cause the metal interconnects 218(1)-218(X) to be larger in size (e.g., width) to reliably achieve an aligned, low resistance via connection. For example, the size (e.g., width W₂) of the first metal interconnects 218(1) in the package substrate 202 in FIG. 2B drive the bump pitch P₂ of the package substrate 202 in the horizontal direction(s) (X-axis and/or Y-axis direction(s)), which in turn drives the number of connections that can be provided between devices, such as the die 206, PMIC 210, and DTC 214 and the package substrate 202, as shown in FIG. 2A. Thus, it may be desired to be able to reduce the widths W₂, W₃ of the first and second metal interconnects 218(1), 218(2) in the package substrate 202, but also maintain a good, low resistance connection with the respective vias 220(1), 220(2).

In this regard, as shown in FIG. 2B, the metallization layers 216(1)-216(X) in the package substrate 202 include respective metal layers 222(1)-222 (X). The first metal layer 222(1) is adjacent to the first, die side 208(1) of the package substrate 202, and the metal layer 222 (X) is adjacent to the second, land side 208(2) of the package substrate 202. Each metal layer 222(1)-222 (X) contains respective metal interconnects 218(1)-218(X) that were formed from the metal layer 222(1)-222 (X) during fabrication of the respective metallization layer 216(1)-216(X). In this example, since the package substrate 202 is an ETS 204, the first and second metal layers 222(1), 222(2) are at least partially (i.e., either partially or fully) embedded in respective first and second insulating layers 224(1), 224(2) such that their respective first and second metal interconnects 218(1), 218(2) are embedded metal traces, and thus also referred to as first and second embedded metal traces 218(1), 218(2), embedded in the respective first and second insulating layers 224(1), 224(2). The first and second insulating layers 224(1), 224(2) are made of a dielectric material in this example.

As discussed in more detail below, to reduce the aspect ratio of the first and second vias 220(1), 220(2) to allow for the respective sizes, (e.g., widths W₂, W₃) of the first and second embedded metal traces 218(1), 218(2) to be reduced, to reduce the bump pitch P₂ of the ETS 204, the first and second insulating layers 224(1), 224(2) include respective first and second metal pad layers 226(1), 226(2), also referred to herein as additional metal pad layers 226(1), 226(2). The first and second metal pad layers 226(1), 226(2) may be referred to herein as “additional” metal pad layers, because the first and second metal pad layers 226(1), 226(2) are metal layers that are provided in addition to the metal layers 222(1), 222(2) in their respective metallization layers 216(1), 216(2) in the package substrate 202 in this example. The first and second additional metal pad layers 226(1), 226(2) each include respective first and second metal pads 228(1), 228(2) in the respective first and second insulating layers 224(1), 224(2). The first and second metal pads 228(1), 228(2) are also referred to herein as first and second additional metal pads 228(1), 228(2). The first and second additional metal pads 228(1), 228(2) are in contact with respective adjacent first and second embedded metal traces 218(1), 218(2) and the respective adjacent first and second vias 220(1), 220(2) in their respective first and second metallization layers 216(1), 216(2). The first and second additional metal pads 228(1), 228(2) provide an electrical connection or conduit between the respective embedded metal traces 218(1), 218(2) and respective first and second vias 220(1), 220(2). In this manner, the first and second vias 220(1), 220(2) do not have to be formed all the way down to the respective first and second embedded metal traces 218(1), 218(2), which would cause their respective aspect ratios to be larger and cause the size (e.g., the width W₄, diameter D₂) of the first and second vias 220(1), 220(2) to be larger. The first and second vias 220(1), 220(2) can be of a reduced height H₂, which in turn reduces their aspect ratio and thus allows the sizes (e.g., widths W₃, W₄) of the respective first and second embedded metal traces 218(1), 218(2) to be reduced while still providing an aligned and low resistance connection with the first and second vias 220(1), 220(2).

As shown in FIG. 2B, the second metallization layer 216(2) is coupled to the first metallization layer 216(1) such that a second, bottom surface 229(2) of the first metallization layer 216(1) is coupled to a third, top surface 229(3) of the second metallization layer 216(2). A first, top surface 229(1) of the first metallization layer 216(1) is adjacent to the first, die side 208(1) of the ETS 204. A fourth, bottom surface 229(4) of the second metallization layer 216(3) is coupled to the metallization layer 216(X). These couplings of the metallization layers 216(1)-216(X) allow the embedded metal traces 218(1), 218(2) and metal interconnects 218(X) to be placed in contact with adjacent vias 220(1), 220(2) to provide signal routing paths. The embedded metal traces 218(1) of the first metallization layer 216(1) can be exposed from a solder resist layer 230 as shown in FIG. 2B to allow a metal bump to be placed in contact with the embedded metal traces 218(1) to electrically and mechanically couple a device to the ETS 204. This is shown for example in FIG. 2A, wherein metal bumps 232(1) are formed in contact with first embedded metal traces 218(1) to couple die interconnects 234 of the die 206 to the ETS 204. As also shown in FIG. 2A, metal bumps 232(2) are also formed in contact with first embedded metal traces 218(1) to couple metal interconnects 236 of the PMIC 210 to the ETS 204. As also shown in FIG. 2A, metal bumps 232(2) are also formed in contact with the metal interconnects 218(X) in the metallization layer 216(X) to couple metal interconnects 238 of the DTC 214 to the ETS 204.

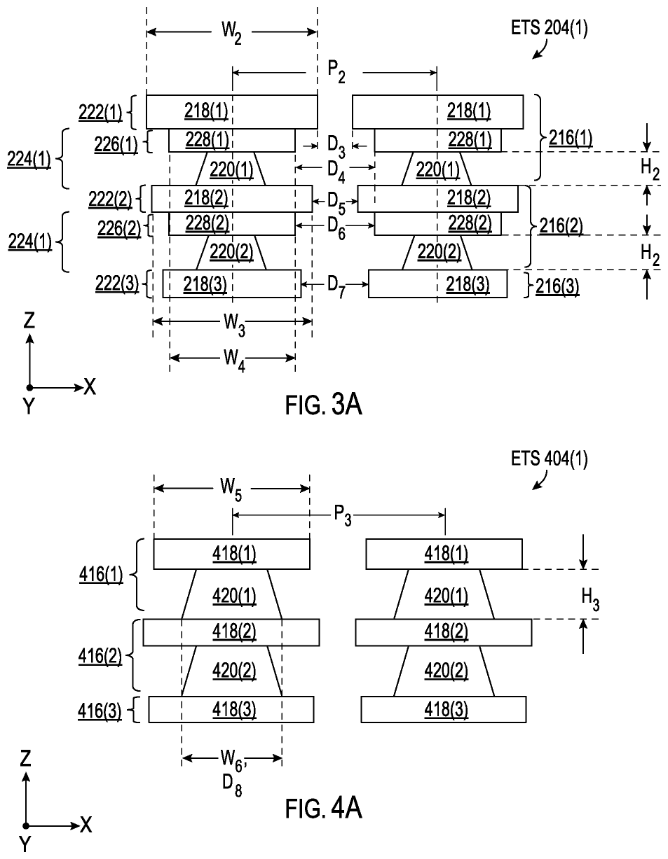

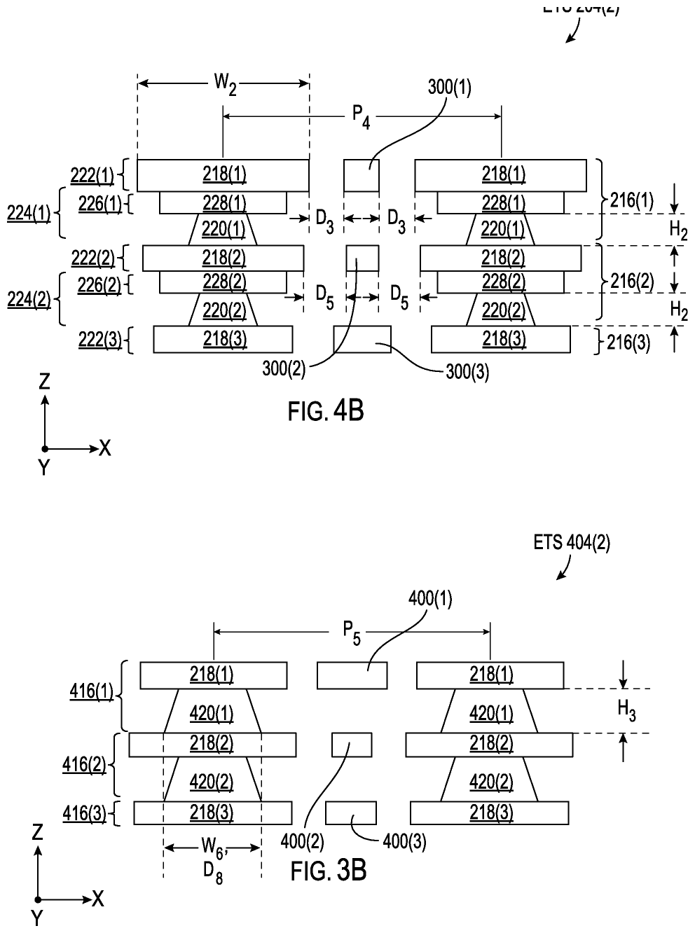

FIG. 3A is a side view of exemplary metallization layers 216(1)-216(3) of an ETS 204(1) that can be the ETS 204 in FIGS. 2A and 2B. Common elements between the ETS 204(1) in FIG. 3A and the ETS 204 in FIGS. 2A and 2B are shown with common element numbers. FIG. 3A illustrates embedded metal traces 218(1), 218(2) and metal interconnects 218(3) interconnected to the first and second vias 220(1), 220(2) through the coupled first and second additional metal pads 228(1), 228(2). As discussed above, the first and second additional metal pad layers 226(1), 226(2) are disposed in the respective first and second insulating layers 224(1), 224(2) of the respective first and second metallization layers 216(1), 216(2). Metallization layer 216(3) could be the metallization layer 216(X) in FIGS. 2A and 2B. As shown in FIG. 3A, the first embedded metal traces 218(1) have the pitch P₂ in the first, horizontal direction(s) (X-axis and/or Y-axis direction(s)). The second embedded metal traces 218(2) and the metal interconnects 218(3) also have the same pitch P₂ in the first, horizontal direction(s) (X-axis and/or Y-axis direction(s)). The first and second additional metal pad layers 226(1), 226(2) also have the same pitch P₂ in the first, horizontal direction(s) (X-axis and/or Y-axis direction(s)). This is in part because these components are aligned in the second, vertical direction (Z-axis direction). As discussed above, by providing the first and second additional metal pad layers 226(1), 226(2) to reduce the height of the first and second vias 220(1), 220(2) in the second, vertical direction (Z-axis direction), this allows the size (e.g., widths W₂, W₃) of the first and second embedded metal traces 218(1), 218(2) to be reduced, thereby allowing the pitch P₂ of the first embedded metal traces 218(1) to be reduced, thereby reducing the bump pitch of the ETS 204(1). For example, the pitch P₂ of the first embedded metal traces 218(1) may be less than or equal to one hundred (100) micrometers (μm). As another example, the pitch P₂ of the first embedded metal traces 218(1) may be less than or equal to eighty (80) μm.

Also in this example, as shown in FIG. 3A, the widths W₂, W₃ of the first and second embedded metal traces 218(1), 218(2) are greater than the width W₄ of the first and second additional metal pads 228(1), 228(2). For example, the width W₂ of the first embedded metal traces 218(1) may be at least fifteen (15) μm greater than the width W₄ of the first additional metal pads 228(1). Also, as another example, the width W₃ of the second embedded metal traces 218(2) may be at least fifteen (15) μm greater than the width W₄ of to the second additional metal pads 228(2). Further, in this example, a first distance D₃ between adjacent first embedded metal traces 218(1) in the first metallization layer 216(1) in the first, horizontal direction(s) (X-axis and/or Y-axis direction(s)) may be less than a distance D₄ between adjacent first additional metal pads 228(1) in the first metallization layer 216(1) in the first, horizontal direction(s) (X-axis and/or Y-axis direction(s)). Further, in this example, the distance D₅ between adjacent second embedded metal traces 218(2) in the second metallization layer 216(2) in the first, horizontal direction(s) (X-axis and/or Y-axis direction(s)) may be greater than the distance De between adjacent second additional metal pads 228(2) in the second metallization layer 216(2) in the first, horizontal direction(s) (X-axis and/or Y-axis direction(s)). For example, the distance D₃ between adjacent first embedded metal traces 218(1) in the first metallization layer 216(1) and/or the distance D₅ between adjacent second embedded metal traces 218(2) in the second metallization layer 216(2) may be fifteen (15) μm. As another example, the distance D₄ between adjacent first additional metal pads 228(1) in the first metallization layer 216(1) and/or the distance De between adjacent second additional metal pads 228(2) in the second metallization layer 216(2) in the first, horizontal direction(s) (X-axis and/or Y-axis direction(s)) may be twenty (20) μm. The distance D₇ in the first, horizontal direction(s) (X-axis and/or Y-axis direction(s)) between adjacent metal interconnects 218(3) in the third metallization layer 216(3) may be thirty (30) μm.

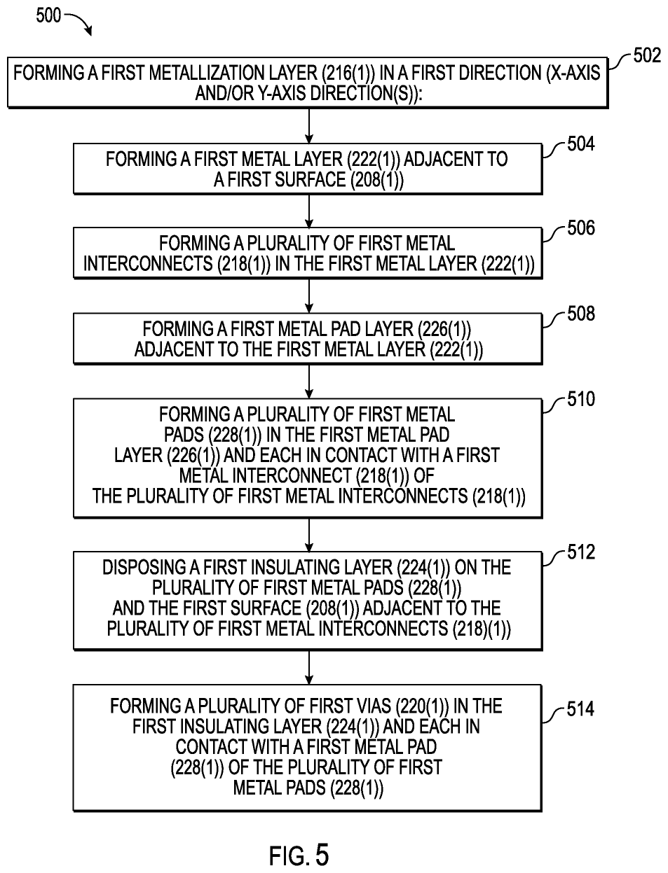

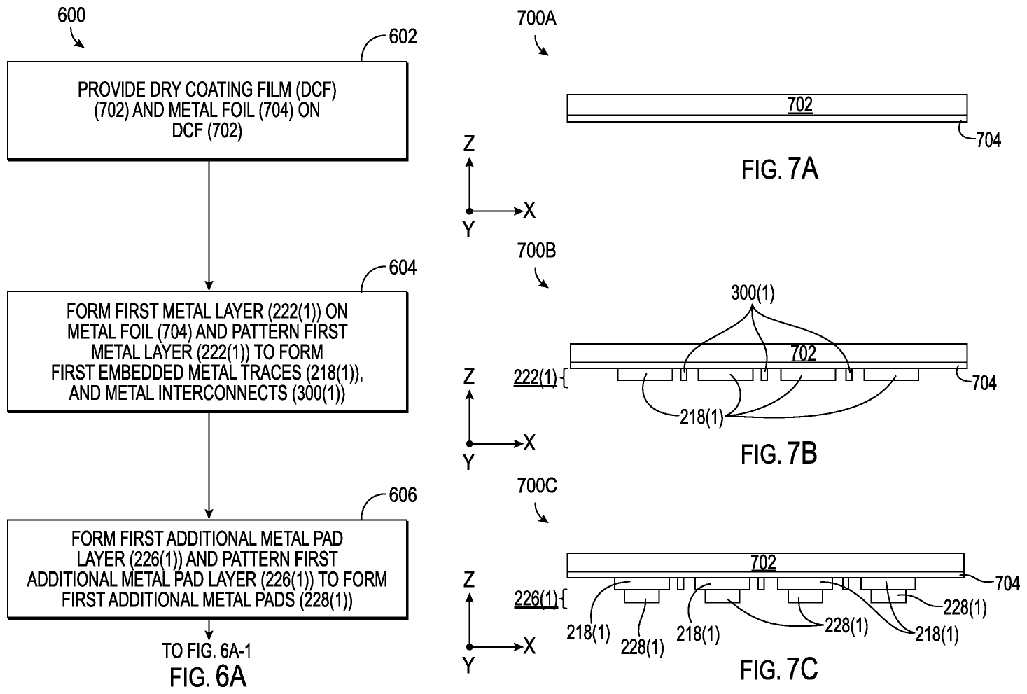

FIG. 4A is a side view of exemplary metallization layers of an ETS 404(1) illustrating metal interconnects interconnected through vias without the inclusion of additional metal pads like the additional metal pads 228(1), 228(2) in the ETS 204(1) in FIG. 3A. Note the width W₅ of metal interconnects 418(1)-418(3) in respective metallization layers 416(1)-416(3) is greater than the width W₂ of the first embedded metal traces 218(1) in the ETS 204(1) in FIG. 3A. This is because the additional metal pads are not provided between the respective metal interconnects 418(1), 418(2) and 418(2), 418(3). Thus, the vias 420(1), 420(2) have a larger height H₃ which in turn causes the vias 420(1), 420(2) to have a larger aspect ratio and size in terms of width W₆ or diameter D₈. This, in turn causes the width W₅ of the metal interconnects 418(1)-418(3) to be larger thus increasing the pitch P₃ between the metal interconnects 418(1)-418(3), which in turn causes the bump pitch of the ETS 404(1) to be greater than the bump pitch of the ETS 204(1) in FIG. 3A.

FIG. 3B is a side view of other exemplary metallization layers 216(1)-216(3) of an ETS 204(2) that can be provided in the ETS 204 in FIGS. 2A and 2B and is similar to the ETS 204(1) in FIG. 3A. Common elements between the ETS 204(2) in FIG. 3B and the ETS 204, 204(1) in FIGS. 2A-3A are shown with common element numbers. As shown in FIG. 3B, the metallization layers 216(1)-216(3) of the ETS 204(2) include intervening metal interconnects 300(1)-300(3) that are disposed between adjacent embedded metal traces 218(1), 218(2) and metal interconnects 218(3) in the first, horizontal direction (X-axis direction). The intervening metal interconnects 300(1)-300(3) may be a ground plane in the ETS 204(2) as an example. The intervening metal interconnects 300(1)-300(3) are not coupled to additional metal pads in the insulating layers 224(1)-224(2) like the additional metal pads 228(1)-228(2) coupled to the respective embedded metal traces 218(1), 218(2). Note that the embedded metal traces 218(1)-218(2), and metal interconnects 218(3) in the ETS 204(2) in FIG. 3B have a pitch P₄ that is larger than the pitch P₂ in the ETS 204(1) in FIG. 3A. However, due to the additional metal pads 228(1)-228(2) provided in the respective metallization layers 216(1)-216(2) of the ETS 204(2), the pitch P₄ of the embedded metal traces 218(1)-218(2), and metal interconnects 218(3) in the ETS 204(2) is less than the pitch P₅ of a similar ETS 404(2) shown in FIG. 4B with intervening metal interconnects 400(1)-400(3) that does not include the additional metal pads 228(1)-228(2).

A package substrate that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate, including, but not limited to, the package substrate 202 in FIGS. 2A-2B, and the ETSs 204, 204(1), 204(2) in FIGS. 2A-3B can be fabricated in different fabrication processes.

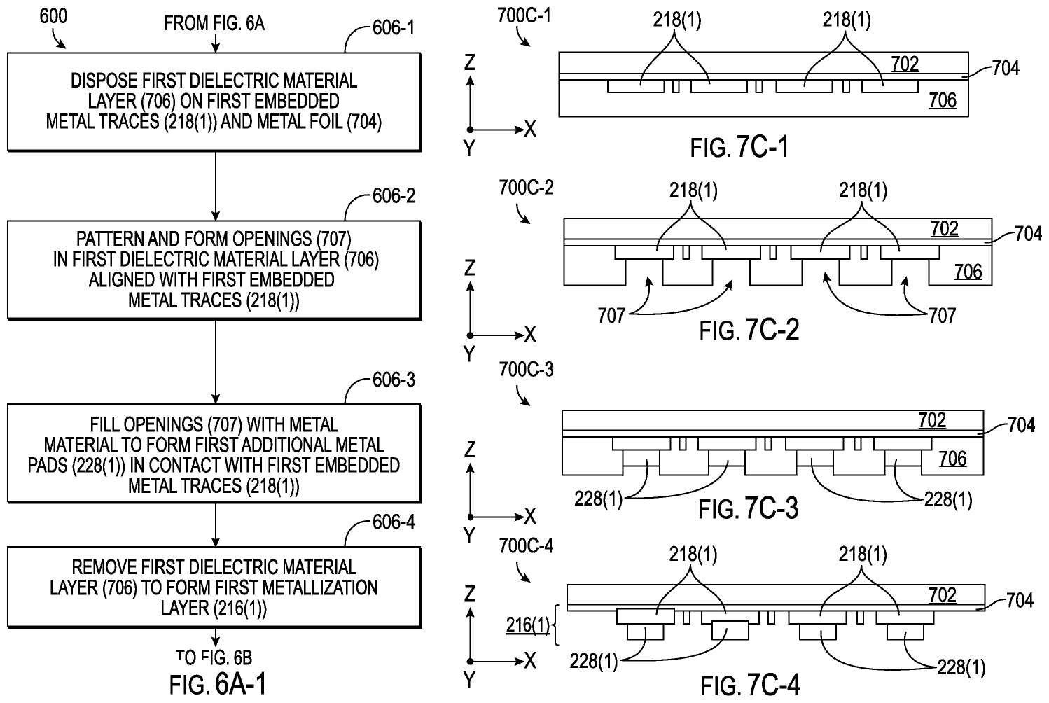

In this regard, FIG. 5 is a flowchart illustrating an exemplary fabrication process 500 of fabricating a package substrate that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate, including, but not limited to, the package substrate 202 in FIGS. 2A-2B. The fabrication process 500 may be used to fabricate an ETS that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the ETS, like the ETSs 204, 204(1), 204(2) in FIGS. 2A-2B and 3A-3B as an example. The fabrication process 500 in FIG. 5 will now be discussed in conjunction with fabricating the metallization layer 216(1) in the package substrate 202, ETS 204 in FIGS. 2A-2B, but note that such is not limiting.

In this regard, a first step in the fabrication process 500 in FIG. 5 can include forming a first metallization layer 216(1) in a first direction (X-axis and/or Y-axis direction(s) (block 502 in FIG. 5). The process of forming the first metallization layer 216(1) can include forming a first metal layer 222(1) adjacent to a first surface 208(1) (block 504 in FIG. 5). The process of forming the first metallization layer 216(1) can also include forming a plurality of first metal interconnects 218(1) in the first metal layer 222(1) (block 506 in FIG. 5). The process of forming the first metallization layer 216(1) can also include forming a first additional metal pad layer 226(1) adjacent to the first metal layer 222(1) (block 508 in FIG. 5). The process of forming the first metallization layer 216(1) can also include forming a plurality of first additional metal pads 228(1) in the first additional metal pad layer 226(1) and each in contact with a first metal interconnect 218(1) of the plurality of first metal interconnects 218(1) (block 510 in FIG. 5). The process of forming the first metallization layer 216(1) can also include disposing a first insulating layer 224(1) on the plurality of first additional metal pads 228(1) and the first surface 208(1) adjacent to the plurality of first metal interconnects 218(1) (block 512 in FIG. 5). The process of forming the first metallization layer 216(1) can also include forming a plurality of first vias 220(1) in the first insulating layer 224(1) and each in contact with a first additional metal pad 228(1) of the plurality of first additional metal pads 228(1), the plurality of first vias 220(1) adjacent to a second surface 208(2) opposite the first surface 208(1) in a second direction (Z-axis direction) orthogonal to the first direction (X-axis and/or Y-axis direction(s)) (block 514 in FIG. 5).

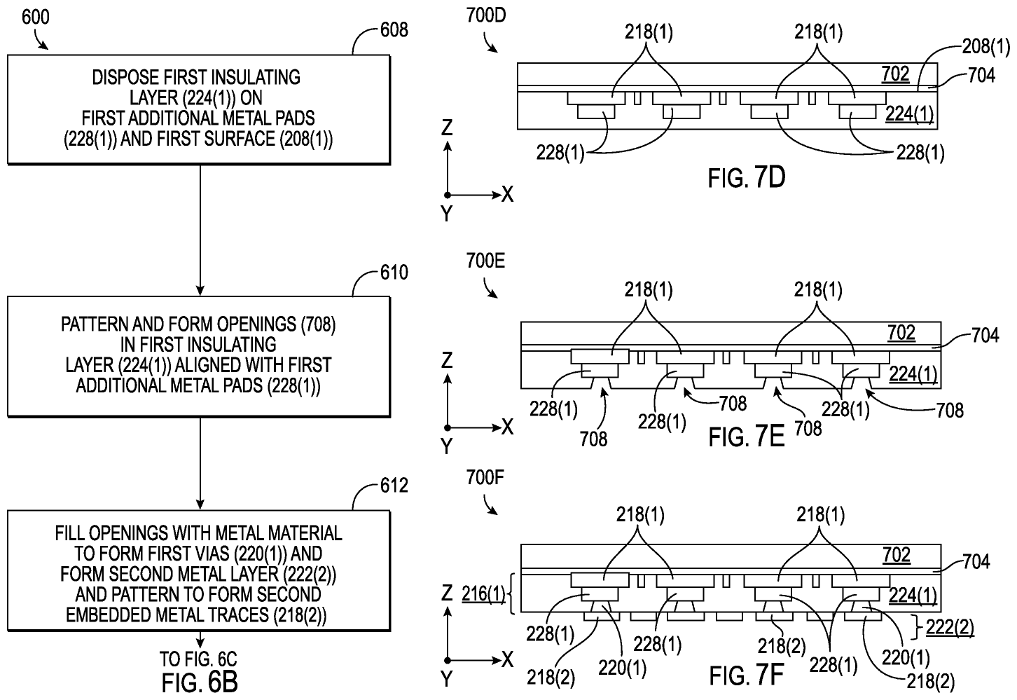

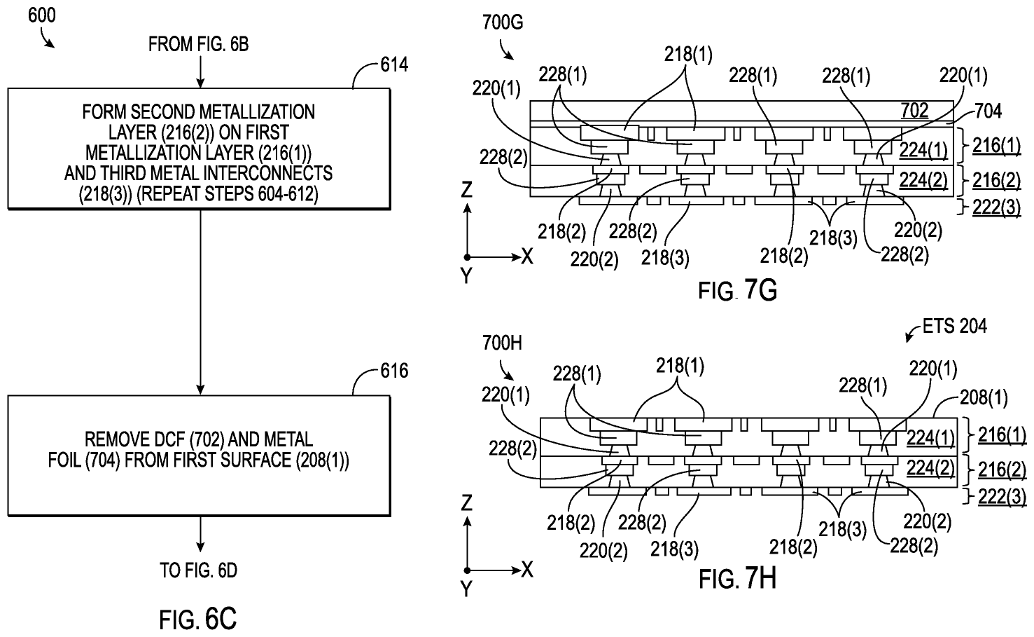

Other fabrication processes can also be employed to fabricate a package substrate in the form of an ETS that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate, including, but not limited to, the ETSs 204, 204(1), 204(2) in FIGS. 2A-3B. In this regard, FIGS. 6A-6D is a flowchart illustrating another exemplary fabrication process 600 of fabricating a package substrate in the form of an ETS that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate, including, but not limited to, the ETSs 204, 204(1), 204(2) in FIGS. 2A-3B. FIGS. 7A-71 are exemplary fabrication stages 700A-700I during fabrication of the ETS according to the fabrication process 600 in FIGS. 6A-6D. The fabrication process 600 as shown in the fabrication stages 700A-700I in FIGS. 7A-7I are in reference to the ETS 204 and related IC package 200 in FIGS. 2A and 2B, but note that the fabrication process 600 could be employed to fabricate another ETS including the ETSs 204(1), 204(2) in FIGS. 3A and 3B.

In this regard, as shown the fabrication stage 700A in FIG. 7A, a first exemplary step in the fabrication process 600 is to provide a dry coating film (DCF) 702 and a metal foil 704 on the DCF 702 to prepare for formation of the first metallization layer 216(1) of the ETS 204 (block 602 in FIG. 6A). Then, as shown the fabrication stage 700B in FIG. 7B, a next exemplary step in the fabrication process 600 is to form the first metal layer 222(1) on the metal foil 704 and pattern the first metal layer 222(1) to form the first embedded metal traces 218(1) and the intervening metal interconnects 300(1) (block 604 in FIG. 6A). A photolithography process may be used to pattern and form the embedded metal traces 218(1) in the first metal layer 222(1) as an example. The intervening metal interconnects 300(1) will not be coupled to additional metal pads. As an example, the intervening metal interconnects 300(1) may be part of a ground plane provided in the ETS 204 to be formed. Then, as shown the fabrication stage 700C in FIG. 7C, a next exemplary step in the fabrication process 600 is to form the first additional metal pad layer 226(1) on the first embedded metal traces 218(1) and pattern the first additional metal pad layer 226(1) to form the first additional metal pads 228(1) in contact with the first embedded metal traces 218(1) (block 606 in FIG. 6A). A photolithography process may be used to pattern and form the first additional metal pads 228(1) in the first additional metal pad layer 226(1) as an example.

Fabrication stages 700C-1-700C-4 in FIGS. 7C-1-7C-4 illustrate the exemplary fabrication stages for forming the first additional metal pads 228(1) in contact with the first embedded metal traces 218(1) (block 606 in FIG. 6A). In this regard, as shown in the fabrication stage 700C-1 in FIG. 7C-1, a next step to form the first additional metal pads 228(1) in contact with the first embedded metal traces 218(1) is to dispose a first dielectric material layer 706 on the first embedded metal traces 218(1) and metal foil 704 (block 606-1 in FIG. 6A-1). Then, as shown in the fabrication stage 700C-2 in FIG. 7C-2, a next step to form the first additional metal pads 228(1) in contact with the first embedded metal traces 218(1) is to pattern and form openings 707 in the first dielectric material layer 706 that are aligned with the first embedded metal traces 218(1) in the second, vertical direction (Z-axis direction) (block 606-2 in FIG. 6A-1). This is to prepare to form the first additional metal pads 228(1) in contact with the first embedded metal traces 218(1). A photolithography process may be used to pattern and form the openings 707 in the first dielectric material layer 706 as an example. Then, as shown in the fabrication stage 700C-3 in FIG. 7C-3, a next step to form the first additional metal pads 228(1) in contact with the first embedded metal traces 218(1) is to fill the openings 707 with a metal material to form the first additional metal pads 228(1) in contact with the first embedded metal traces 218(1) (block 606-3 in FIG. 6A-1). Then, as shown in the fabrication stage 700C-4 in FIG. 7C-4, a next step to form the first additional metal pads 228(1) in contact with the first embedded metal traces 218(1) is to remove the first dielectric material layer 706 from the first additional metal pads 228(1) (block 606-4 in FIG. 6A-1).

Then, as shown in the fabrication stage 700D in FIG. 7D, a next step to form the first metallization layer 216(1) is to dispose the first insulating layer 224(1) on the first additional metal pads 228(1) and the first surface 208(1) (block 608 in FIG. 6B). Then, as shown in the fabrication stage 700E in FIG. 7E, a next step to form the first metallization layer 216(1) is to pattern and form openings 708 in the first insulating layer 224(1) aligned with the first additional metal pads 228(1) to prepare for the first vias 220(1) to be formed in contact with the first additional metal pads 228(1) (block 610 in FIG. 6B). A photolithography process may be used to pattern and form the openings 708 in the first insulating layer 224(1) as an example. Then, as shown in the fabrication stage 700F in FIG. 7F, a next step to form the first metallization layer 216(1) is to fill the openings 708 in the first insulating layer 224(1) with a metal material to form the first vias 220(1) and the second metal layer 222(2) (block 612 in FIG. 6B). Because of the presence of the first additional metal pads 228(1), the aspect ratio and height of the first vias 220(1), 220(2) is reduced, thereby allowing the first embedded metal traces 218(1) to be formed of a reduced size and having a reduced pitch as discussed previously. The second metal layer 222(2) can then be patterned to form the second embedded metal traces 218(2) like the first metal layer 222(1) was patterned to form the first embedded metal traces 218(1) as discussed above (block 612 in FIG. 6B).

Then, as shown in the fabrication stage 700G in FIG. 7G, a next step to form the ETS 204 is to form the second metallization layer 216(2) on and coupled to the first metallization layer 216(1) and the third metal interconnects 218(3) coupled to the second metallization layer 216(2) (block 614 in FIG. 6C). The same steps 604-612 previously discussed above can be used in a repeated fashion to form the second metallization layer 216(2) and third metal interconnects 218(3). The second metallization layer 216(2) and third metal interconnects 218(3) are formed such that the second embedded metal traces 218(2) of the second metallization layer 216(2) are in contact with respective first vias 220(1) of the first metallization layer 216(1), and the third metal interconnects 218(3) are in contact with respective second vias 220(2) of the second metallization layer 216(2). Then, as shown in the fabrication stage 700H in FIG. 7H, a next step to form the ETS 204 is to remove the DCF 702 and metal foil 704 from the first surface 208(1) (block 616 in FIG. 6D). Then, as shown in the fabrication stage 700I in FIG. 7I, a next step to form the ETS 204 is to form solder resist layers 710, 712 in contact with the respective first and second surfaces 208(1), 208(2) and to pattern the solder resist layers 710, 712 to form respective openings 714, 716 adjacent to the first embedded metal traces 218(1) and third metal interconnects 218(3) (block 618 in FIG. 6D). This is to expose the first embedded metal traces 218(1) and third metal interconnects 218(3) from the solder resist layers 710, 712, so that bumps can be formed in contact with the embedded metal traces 218(1) and third metal interconnects 218(3) to provide signal routing paths to the ETS 204.

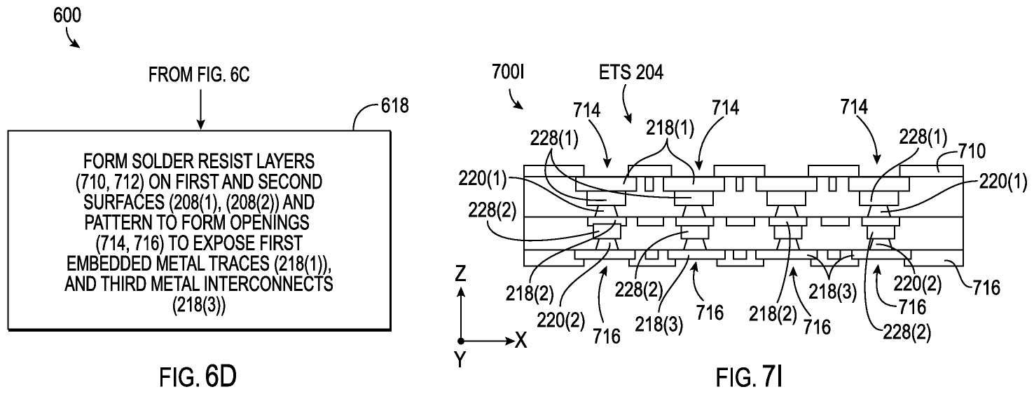

A package substrate that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate can also be provided in other forms of package substrates. For example, FIG. 8 is a side view of another exemplary package substrate 802 in the form of a SAP substrate 804 in this example (e.g., a modified SAP (mSAP)). The SAP substrate 804 could be provided as the package substrate 202 in the IC package in FIGS. 2A and 2B if desired. Common elements between the SAP substrate 804 in FIG. 8 and the package substrate 202 in FIGS. 2A and 2B are shown with common element numbers.

With reference to FIG. 8, the SAP substrate 804 includes one or more metallization layers 816(1)-816(4). The SAP substrate 804 also includes a core layer 806. The metallization layers 816(1)-816(4) and the core layer 806 extend in a first, horizontal direction(s) (X-axis and/or Y-axis direction(s)). Devices, such as the PMIC 210 and DTC 214 in the IC package 200 in FIG. 2A, can be electrically coupled to the metallization layers 816(1)-816(4) in the SAP substrate 804. If electrical couplings involve signal routing through a lower metallization layer 816(2)-816(4), a first metal interconnect 818(1) is coupled to other adjacent metal interconnects 818(2)-818(4) through one or more respective first and second vias 820(1), 820(2) to provide a signal routing path from a first surface 808(1) of the SAP substrate 804 to a second surface 808(2) of the SAP substrate 804 opposite of the first surface 808(1) in the second, vertical direction (Z-axis direction).

As shown in the SAP substrate 804 in FIG. 8, the size (e.g., width W₇) of the first and fourth metal interconnects 818(1), 818(4) in the respective metallization layers 816(1), 816(4) should be sufficiently sized to allow for the aligned formation of the first and second vias 820(1), 820(2) to be electrically coupled to the first and fourth metal interconnects 818(1), 818(4) with a low resistance connection. For example, the vias 820(1), 820(2) may be formed by drilling an opening into their respective second and third metallization layers 816(2), 816(3) down to the respective second and third metal interconnects 818(2), 818(3) as part of the fabrication of the second and third metallization layers 816(2), 816(3) and then filling in the openings with a metal material. However, a larger vertical height H₄ between the first and second metal interconnects 818(1), 818(2) and between the third and fourth metal interconnects 818(3), 818(4) in the second, vertical direction (Z-axis direction) could result in the first and second vias 820(1). 820(2) having a larger aspect ratio that then may cause the first and fourth metal interconnects 818(1), 818(4) to be larger in size (e.g., width) to reliably achieve an aligned, low-resistance via connection. For example, the size (e.g., width W₈) of the first and fourth metal interconnects 818(1), 818(4) in the SAP substrate 804 drive the bump pitch P₆ of the SAP substrate 804 in the horizontal direction(s) (X-axis and/or Y-axis direction(s)), which in turn drives the number of connections that can be provided between devices and the SAP substrate 804. Thus, it may be desired to be able to reduce the widths W₇ of the first and fourth metal interconnects 818(1), 818(4) in the SAP substrate 804, but also maintain a good, low resistance connection with the respective vias 820(1), 820(2).

In this regard, as shown in FIG. 8, the metallization layers 816(1)-816(4) in the SAP substrate 804 include respective metal layers 822(1)-822(4). The first metal layer 822(1) is adjacent to the first, die side 808(1) of the SAP substrate 804, and the fourth metal layer 822(4) is adjacent to the second, land side 808(2) of the SAP substrate 804. Each metal layer 822(1)-822(4) contains respective metal interconnects 818(1)-818 (4) that were formed from the metal layers 822(1)-822(4) during fabrication of the respective metallization layers 816(1)-816(4). In this example, the metal interconnects 818(2), 818(3) are formed adjacent to respective insulating layers 824(2), 824(3), and the metal interconnects 818(1), 818(4) are formed adjacent to respective solder resist layers 830, 832. The insulating layers 824(2), 824(3) and solder resist layers 830, 832 are made of a dielectric material in this example.

To reduce the aspect ratio of the first and second vias 820(1), 820(2) to allow for the respective sizes (e.g., widths W₇) of the first and fourth metal interconnects 818(1), 818(4) to be reduced, to reduce the bump pitch P₆ of the SAP substrate 804, the first and second insulating layers 824(1), 824(2) include respective first and second metal pad layers 826(1), 826(2), also referred to as first and second additional metal pad layers 826(1), 826(2). The first and second metal pad layers 826(1), 826(2) may be referred to herein as first and second “additional” metal pad layers, because the first and second metal pad layers 826(1), 826(2) are metal layers that are provided in addition to the metal layers 822(2), 822(3) in their respective metallization layers 816(2), 816(3) in the package substrate 802 in this example. The first and second additional metal pad layers 826(1), 826(2) each include respective first and second metal pads 828(1), 828(2) in the respective first and second insulating layers 824(1), 824(2). The first and second metal pads 828(1), 828(2) are also referred to herein as first and second additional metal pads 828(1), 828(2). The first and second additional metal pads 828(1), 828(2) are in contact with respective adjacent second and third metal interconnects 818(2), 818(3) and the respective adjacent first and second vias 820(1), 820(2) in their respective second and third metallization layers 816(1), 816(2). The first and second additional metal pads 828(1), 828(2) provide an electrical connection or conduit between the respective metal interconnects 818(2), 818(3) and respective first and second vias 820(1), 820(2). In this manner, the first and second vias 820(1), 820(2) do not have to be formed all the way down to the respective second and third metal interconnects 818(2), 818(3), which would cause their respective aspect ratios to be larger and cause the size (e.g., the width W₈, diameter D₇) of the first and second vias 820(1), 820(2) to be larger. The first and second vias 820(1), 820(2) can be of a reduced height H₅, which in turn reduces their aspect ratio and thus allows the sizes (e.g., widths W₇) of the respective first and fourth metal interconnects 818(1), 818(4) to be reduced while still providing an aligned and low resistance connection with the first and second vias 820(1), 820(2) to the respective second and third metal interconnects 818(2), 818(3).

As shown in FIG. 8, the first metallization layer 816(1) is coupled to the second metallization layer 816(2) such that a second, bottom surface 829(2) of the first metallization layer 816(1) is coupled to a third, top surface 829(3) of the second metallization layer 816(2). A fourth, bottom surface 829(4) of the third metallization layer 816(3) is coupled to the fourth metallization layer 816(4). These couplings of the metallization layers 816(1)-816(4) allow the second and third metal interconnects 818(2), 818(3) to be placed in contact with adjacent first and second vias 820(1), 820(2) to provide signal routing paths. The core layer 806 in this example also includes third and fourth vias 820(3), 820(4) that are coupled to respective adjacent second and third metal interconnects 818(2), 818(3) to provide signal routing paths between the second and third metallization layers 816(2), 816(3). The first metal interconnects 818(1) of the first metallization layer 816(1) can be exposed from a solder resist layer 830 to allow a metal bump to be placed in contact with the first metal interconnects 818(1) to electrically and mechanically couple a device to the SAP substrate 804. The fourth metal interconnects 818(4) of the fourth metallization layer 816(4) can also be exposed from a solder resist layer 832 to allow a metal bump to be placed in contact with the fourth metal interconnects 818(4) to electrically and mechanically couple a device to the SAP substrate 804.

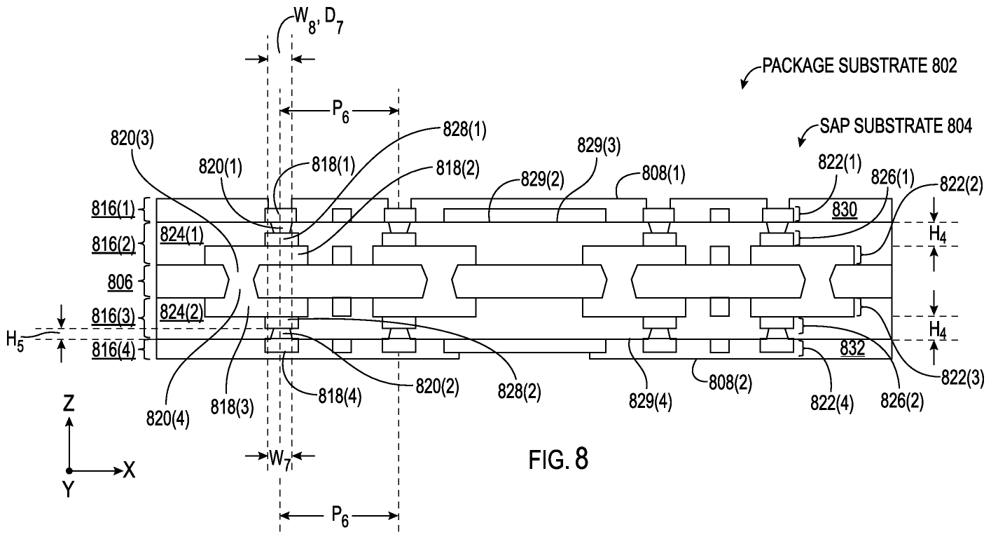

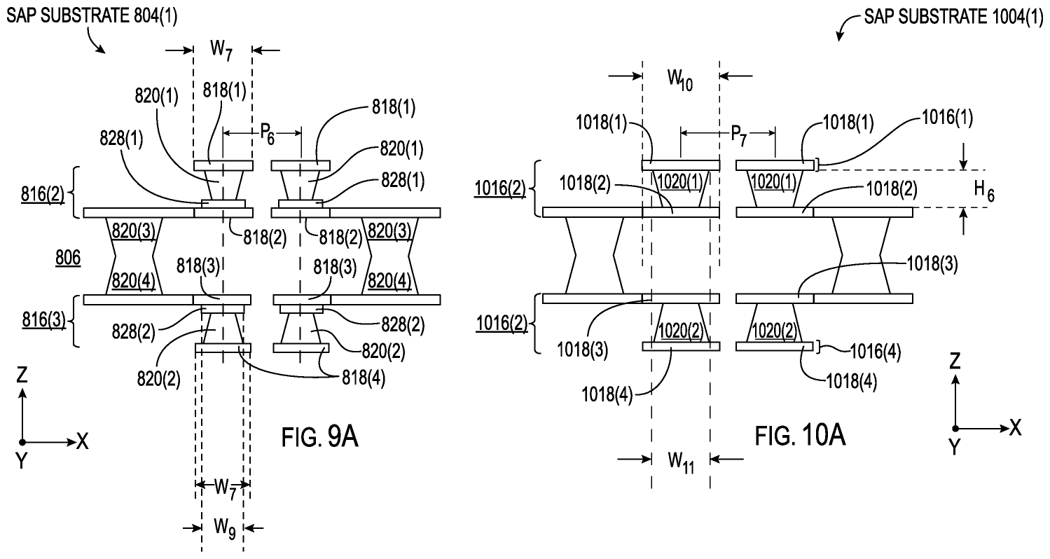

FIG. 9A is a side view of exemplary second and third metallization layers 816(2), 816(3) of a SAP substrate 804(1) that can be the SAP substrate 804 in FIG. 8. Common elements between the SAP substrate 804(1) in FIG. 9A and the SAP substrate 804 in FIG. 8 are shown with common element numbers. FIG. 9A illustrates second and third metal interconnects 818(2), 818(3) interconnected to the first and second vias 820(1), 820(2) through the coupled the first and second additional metal pads 828(1), 828(2). As discussed above, the first and second additional metal pad layers 828(1), 828(2) are disposed in the respective first and second insulating layers 824(1), 824(2) of the respective second and third metallization layers 816(2), 816(3). As shown in FIG. 9A, the first and fourth metal interconnects 818(1), 818(4) have the pitch P₆ in the first, horizontal direction(s) (X-axis and/or Y-axis direction(s)). The second and third metal interconnects 818(2), 818(3) also have the same pitch P₆ in the first, horizontal direction(s) (X-axis and/or Y-axis direction(s)). The first and second additional metal pad layers 826(1), 826(2) also have the same pitch P₇ in the first, horizontal direction(s) (X-axis and/or Y-axis direction(s)). This is in part because these components are aligned in the second, vertical direction (Z-axis direction). As discussed above, by providing the first and second additional metal pad layers 826(1), 826(2) to reduce the height of the first and second vias 820(1), 820(2) in the second, vertical direction (Z-axis direction), this allows the size (e.g., widths W₇) of the first and fourth metal interconnects 818(1), 818(4) to be reduced, thereby allowing the pitch P₆ of the first and fourth metal interconnects 818(1), 818(4) to be reduced, thereby reducing the bump pitch of the SAP substrate 804(1). For example, the pitch P₆ of the first and fourth metal interconnects 818(1), 818(4) may be less than or equal to one hundred (100) micrometers (μm). As another example, the pitch P₆ of the and fourth metal interconnects 818(1), 818(4) may be less than or equal to seventy-five (75) μm. Also in this example, as shown in FIG. 9A, the width W₇ of the first and fourth metal interconnects 818(1), 818(4) is less than the width W₉ of the first and second additional metal pads 828(1), 828(2). For example, the width W₇ of the first and fourth metal interconnects 818(1), 818(4) may be at least five (5) μm greater than the width W₉ of the first and second additional metal pads 828(1), 828(2).

Note that the SAP substrate 804(1) in FIG. 9A could also be provided that does not include the second additional metal pads 828(2) in the third metallization layer 816(3) as another example.

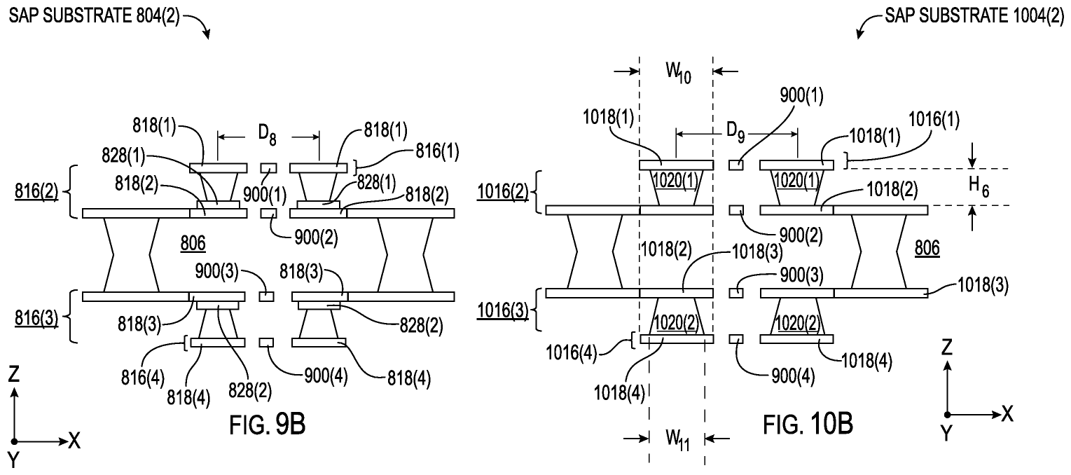

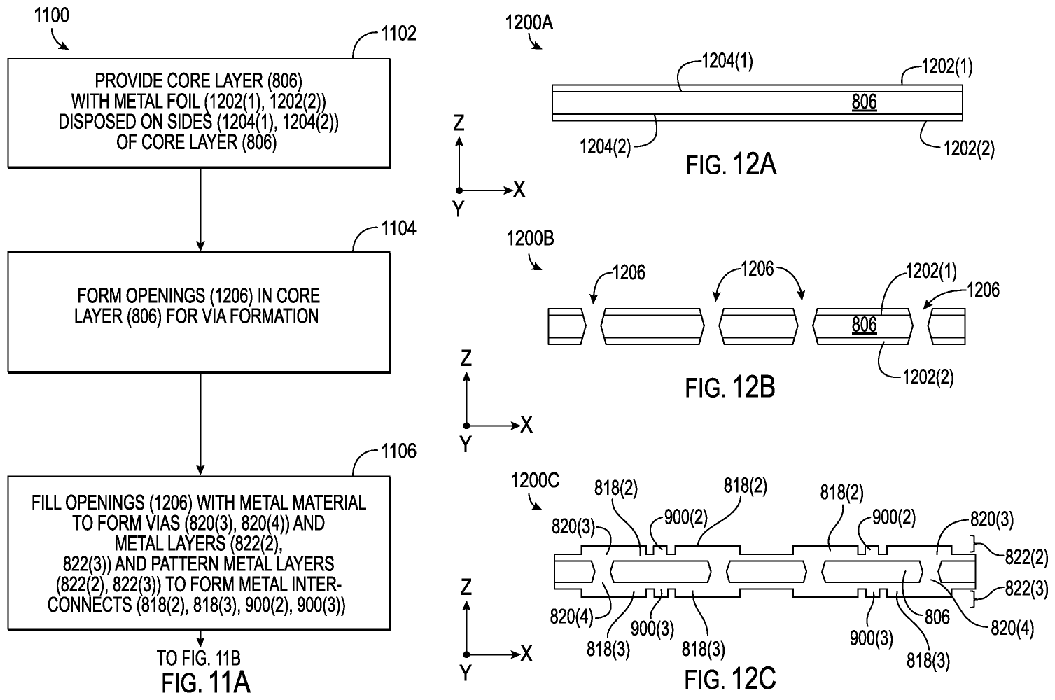

FIG. 10A is a side view of exemplary metallization layers of a SAP substrate 1004(1) illustrating metal interconnects interconnected through vias without the inclusion of additional metal pads like the additional metal pads 828(1), 828(2) in the SAP substrate 804(1) in FIG. 9A. Note the width W₁₀ of metal interconnects 1018(1)-1018(4) in respective metallization layers 1016(1)-1016(4) in the SAP substrate 1004(1) in FIG. 10A is greater than the width W₇ of the first and fourth metal interconnects 818(1), 818(4) in the SAP substrate 804(1) in FIG. 9A. This is because the additional metal pads are not provided between the respective first and second metal interconnects 1018(1). 1018(2), and the respective third and fourth metal interconnects and 1018(3), 1018(4). Thus, vias 1020(1), 1020(2) have a larger height H₆ which in turn causes the vias 1020(1), 1020(2) to have a larger aspect ratio and size in terms of width W₁₁. This in turn causes the width W₁₀ of the first and fourth metal interconnects 1018(1), 1018(4) to be larger thus increasing the pitch P₇ of the first and fourth metal interconnects 1018(1), 1018(4), which in turn causes the bump pitch of the SAP substrate 1004(1) to be greater than the bump pitch P₆ of the SAP substrate 804(1) in FIG. 9A.

FIG. 9B is a side view of other exemplary metallization layers 816(1)-816(4) of a SAP substrate 804(2) that can be provided in the SAP substrate 804 in FIG. 8 and is similar to the SAP substrate 804(1) in FIG. 9A. Common elements between the SAP substrate 804(2) in FIG. 9B and the SAP substrates 804, 804(1) in FIGS. 8 and 9A are shown with common element numbers. As shown in FIG. 9B, the metallization layers 816(1)-816(4) of the SAP substrate 804(2) include intervening metal interconnects 900(1)-900(4) that are disposed between adjacent metal interconnects 818(1)-818(4) in the first, horizontal direction (X-axis direction). The intervening metal interconnects 900(1)-900(4) may be a ground plane in the SAP substrate 804(2) as an example. The intervening metal interconnects 900(1)-900(3) are not coupled to additional metal pads in the insulating layers 824(1)-824(4) (see FIG. 8) like the first and second additional metal pads 828(1), 828(2) coupled to the respective second and third metal interconnects 818(2), 818(3) in the SAP substrate 804 in FIG. 8. Note that the metal interconnects 818(1)-818(4) in the SAP substrate 804(2) in FIG. 9B have a pitch P₈ that is larger than the pitch P₇ in the SAP substrate 804(1) in FIG. 9A. However, due to the additional metal pads 828(1), 828(2) provided in the respective metallization layers 816(2), 816(3) in the SAP substrate 804(2) in FIG. 9B, the pitch P₈ of the metal interconnects 818(1)-818 (4) in the SAP substrate 804(2) is less than the pitch P₉ of a similar SAP substrate 1004(2) shown in FIG. 10B that does not include the additional metal pads 828(1), 828(2).

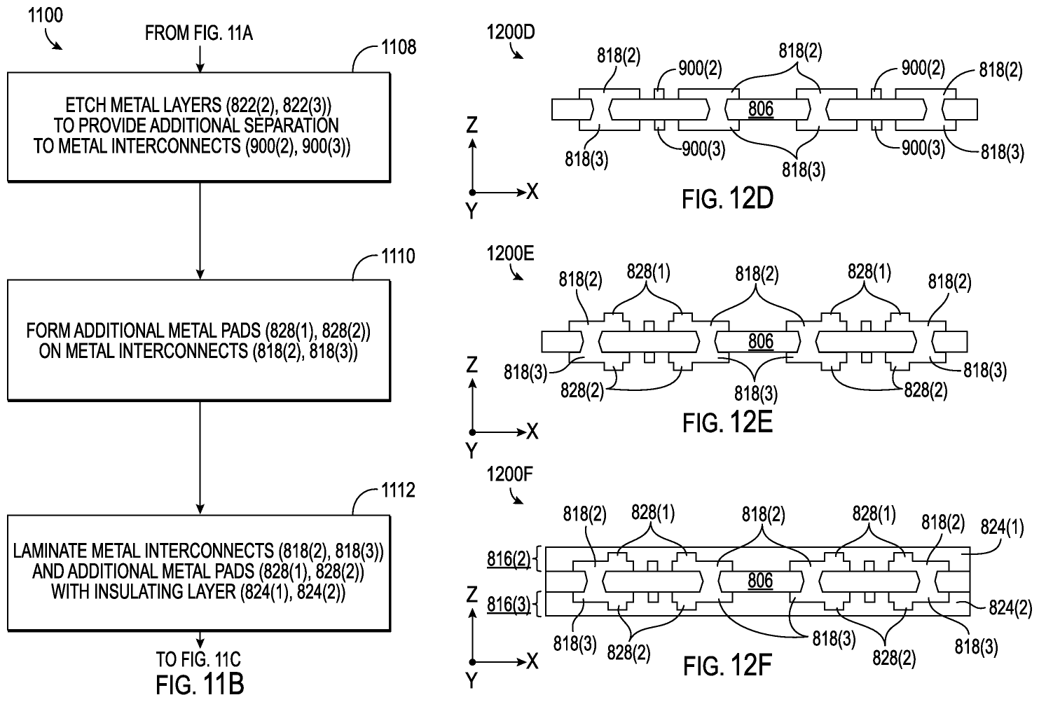

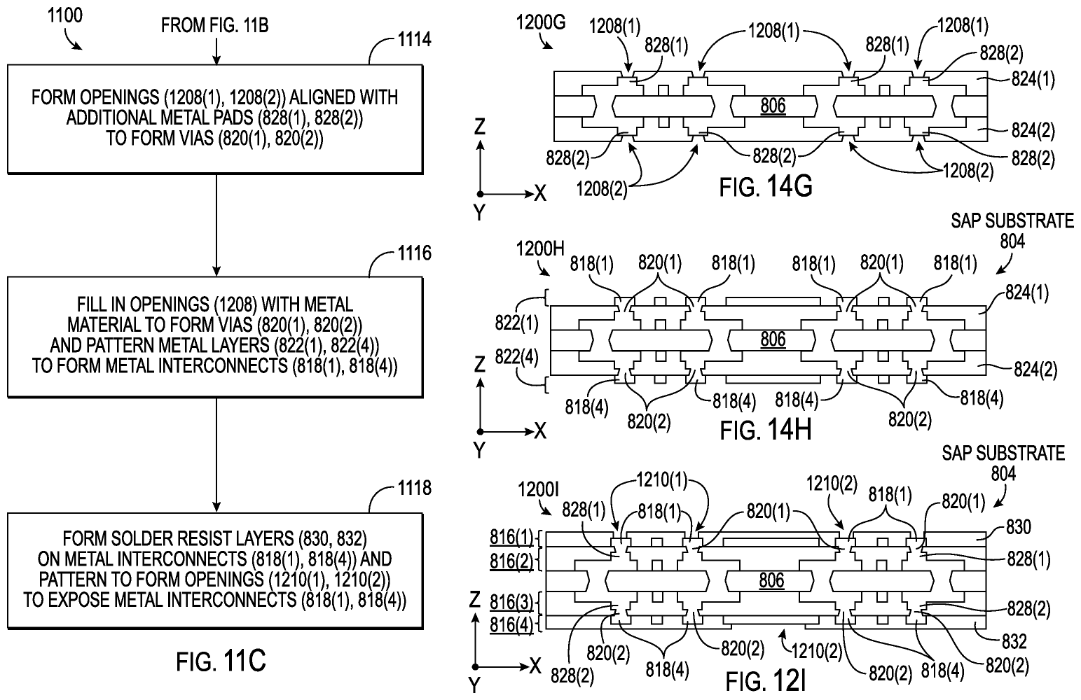

FIGS. 11A-11C is a flowchart illustrating another exemplary fabrication process 1100 of fabricating a package substrate in the form of a SAP substrate that includes metallization layers that include an additional metal pad layer in an insulating layer of a metallization layer electrically coupling a via to a metal interconnect in a metal layer of the metallization layers to facilitate a reduced via size and metal interconnect size to support a reduced bump pitch in the package substrate, including, but not limited to, the SAP substrates 804, 804(1), 804(2) in FIGS. 8-9B. FIGS. 12A-12I are exemplary fabrication stages 1200A-1200I during fabrication of the SAP substrate according to the fabrication process 1100 in FIGS. 11A-11C. The fabrication process 1100 as shown in the fabrication stages 1200A-1200I in FIGS. 12A-12I are in reference to the SAP substrate 804 in FIG. 8, but note that the fabrication process 1100 could be employed to fabricate another SAP substrate including the SAP substrates 804(1), 804(2) in FIGS. 9A and 9B.

In this regard, as shown the fabrication stage 1200A in FIG. 12A, a first exemplary step in the fabrication process 1100 is to provide a core layer 806 and to dispose metal foil 1202(1), 1202(2) on each side 1204(1), 1204(2) of the core layer 806 to prepare for the metallization layers 816(2), 816(3) to be formed (block 1102 in FIG. 11A). Then, as shown the fabrication stage 1200B in FIG. 12B, a next exemplary step in the fabrication process 1100 can be to form openings 1206 in the core layer 806 to prepare for formation of the vias 820(3), 820(4) that will extend through the core layer 806 (block 1104 in FIG. 11A). Then, as shown the fabrication stage 1200C in FIG. 12C, a next exemplary step in the fabrication process 1100 can be to fill the openings 1206 with metal material to form the vias 820(3), 820(4) in the core layer 806 and to form the second and third metal layers 822(3), 822(3) for the second and third metallization layers 816(2), 816(3) (block 1106 in FIG. 11A). The second and third metal layers 822(2), 822(3) and then patterned (e.g., using a lithography process) to form the second and third metal interconnects 818(2). 818(3) and the intervening metal interconnects 900(2). 900(3) for the for the second and third metallization layers 816(2), 816(3) (block 1106 in FIG. 11A).

Then, as shown the fabrication stage 1200D in FIG. 12D, a next exemplary step in the fabrication process 1100 can be to etch the second and third metal layers 822(2), 822(3) to provide additional separation distance between the second and third metal interconnects 818(2), 818(3) and the respective intervening metal interconnects 900(2), 900(3) (block 1108 in FIG. 11B). Then, as shown the fabrication stage 1200E in FIG. 12E, a next exemplary step in the fabrication process 1100 can be to form the first and second additional metal pads 828(1), 828(2) on the second and third metal interconnects 818(2), 818(3) that will be part of the respective second and third metallization layers 816(2), 816(3) (block 1110 in FIG. 11B). Then, as shown the fabrication stage 1200F in FIG. 12F, a next exemplary step in the fabrication process 1100 can be to laminate the second and third metal interconnects 818(2), 818(3) and the first and second additional metal pads 828(1), 828(2) with respective first and second insulating layers 824(1), 824(2) to form the second and third metallization layers 816(2), 816(3) (block 1112 in FIG. 11B). This also disposes the first and second additional metal pads 828(1), 828(2) in the respective first and second insulating layers 824(1), 824(2).

Then, as shown the fabrication stage 1200G in FIG. 12G, a next exemplary step in the fabrication process 1100 can be to form openings 1208(1), 1208(2) aligned with the first and second additional metal pads 828(1), 828(2) in the insulating layers 824(1), 824(2) to prepare to form the first and second vias 820(1), 820(2) down to and in contact with the first and second additional metal pads 828(1), 828(2) (block 1114 in FIG. 11C). Then, as shown the fabrication stage 1200H in FIG. 12H, a next exemplary step in the fabrication process 1100 can be to fill in the openings 1208(1), 1208(2) with metal material to form the first and second vias 820(1), 820(2) and then to pattern the metal layers 822(1), 822(4) formed from the metal material fill to form the metal interconnects 818(1), 818(4) for the respective first and fourth metallization layers 816(1), 816(4) (block 1116 in FIG. 11C). The SAP substrate 804 is now formed with the metallization layers 816(1)-816(4), wherein the second and third metallization layers 816(2), 816(3) include the respective first and second additional metal pads 828(1), 828(2) to reduce the bump pitch of the SAP substrate 804. Then, as shown the fabrication stage 1200I in FIG. 12I, a next exemplary step in the fabrication process 1100 can be to form the solder resist layers 830, 832 on the respective first and fourth metal interconnects 818(1), 818(4) to finalize the formation of the respective first and fourth metallization layers 816(1), 816(4) (block 1118 in FIG. 11C). The solder resist layers 830, 832 can be patterned to form openings 1210(1), 1210(2) in the respective solder resist layers 830, 832 to expose the first and fourth metal interconnects 818(1), 818(4) from the respective first and fourth metallization layers 816(1), 816(4) to prepare for a bump connection process to the SAP substrate 804 (block 1118 in FIG. 11C).

Note that the terms “upper” and “top” where used herein are relative terms and are not meant to limit or imply a strict orientation that a “top” referenced element must always be oriented to be above a “bottom” referenced element, and vice versa. Note that the terms “lower” and “bottom” where used herein are relative terms and are not meant to limit or imply a strict orientation that a “bottom” or “lower” referenced element must always be oriented to be below a “top” or “upper” referenced element, and vice versa. Also, note that the terms “above” and “below” where used herein are relative terms and are not meant to limit or imply a strict orientation that an element referenced as being “above” another referenced element must always be oriented to be above the other referenced element with respect to ground, or that an element referenced as being “below” another referenced element must always be oriented to be below the other referenced element with respect to ground.

An object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

A package substrate that includes metallization layers that include an additional metal pad layer in an insulating layer of a metallization layer electrically coupling a via to a metal interconnect (e.g., an embedded metal trace) in a metal layer of the metallization layers to facilitate a reduced via size and metal interconnect size to support a reduced bump pitch in the package substrate, including, but not limited to, the package substrates in FIGS. 2A-3B, 7I, 8-9B, and 12I, and according to the exemplary fabrication processes in FIGS. 5, 6A-6D, and 11A-11C, and according to any aspects disclosed herein, may be provided in an IC package provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

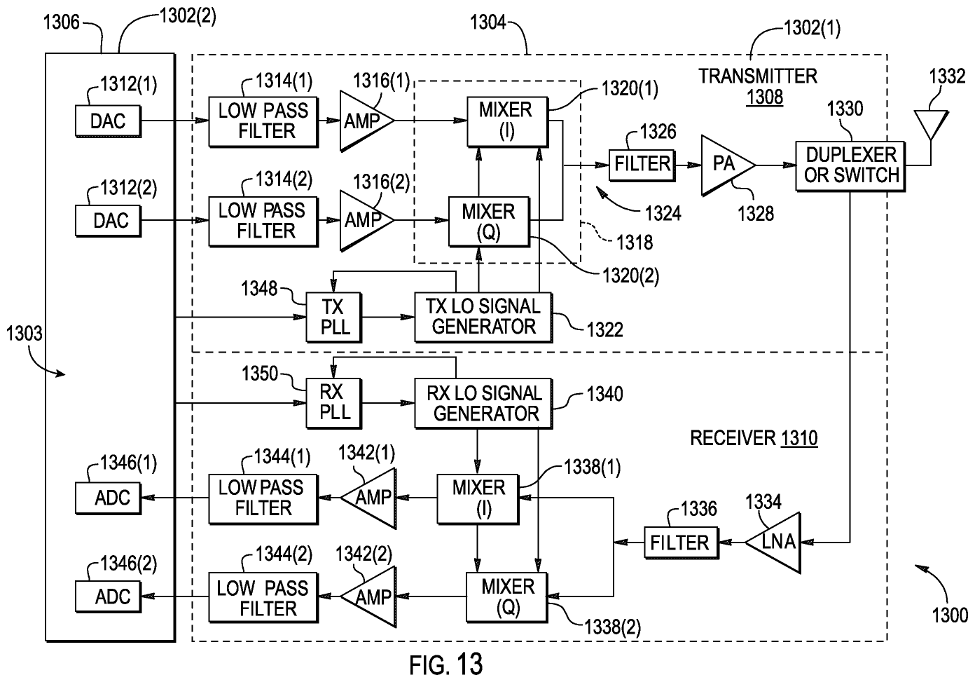

In this regard, FIG. 13 illustrates an exemplary wireless communications device 1300 that includes radio frequency (RF) components formed from one or more IC packages 1302(1), 1302(2), wherein any of the IC packages 1302(1), 1302(2) includes metallization layers that include an additional metal pad layer in an insulating layer of a metallization layer electrically coupling a via to a metal interconnect (e.g., an embedded metal trace) in a metal layer of the metallization layers to facilitate a reduced via size and metal interconnect size to support a reduced bump pitch in the package substrate, including, but not limited to, the package substrates in FIGS. 2A-3B, 7I, 8-9B, and 12I, and according to the exemplary fabrication processes in FIGS. 5, 6A-6D, and 11A-11C, and according to any aspects disclosed herein. The wireless communications device 1300 may include or be provided in any of the above-referenced devices, as examples. As shown in FIG. 13, the wireless communications device 1300 includes a transceiver 1304 and a data processor 1306. The data processor 1306 may include a memory to store data and program codes. The transceiver 1304 includes a transmitter 1308 and a receiver 1310 that support bi-directional communications. In general, the wireless communications device 1300 may include any number of transmitters 1308 and/or receivers 1310 for any number of communication systems and frequency bands. All or a portion of the transceiver 1304 may be implemented on one or more analog ICs, RF ICs (RFICs), mixed-signal ICs, etc.

The transmitter 1308 or the receiver 1310 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1310. In the direct-conversion architecture, a signal is frequency-converted between RF and baseband in one stage. The super-heterodyne and direct-conversion architectures may use different circuit blocks and/or have different requirements. In the wireless communications device 1300 in FIG. 13, the transmitter 1308 and the receiver 1310 are implemented with the direct-conversion architecture.

In the transmit path, the data processor 1306 processes data to be transmitted and provides I and Q analog output signals to the transmitter 1308. In the exemplary wireless communications device 1300, the data processor 1306 includes digital-to-analog converters (DACs) 1312(1), 1312(2) for converting digital signals generated by the data processor 1306 into the I and Q analog output signals, e.g., I and Q output currents, for further processing.

Within the transmitter 1308, lowpass filters 1314(1), 1314(2) filter the I and Q analog output signals, respectively, to remove undesired signals caused by the prior digital-to-analog conversion. Amplifiers (AMPs) 1316(1), 1316(2) amplify the signals from the lowpass filters 1314(1), 1314(2), respectively, and provide I and Q baseband signals. An upconverter 1318 upconverts the I and Q baseband signals with I and Q transmit (TX) local oscillator (LO) signals through mixers 1320(1), 1320(2) from a TX LO signal generator 1322 to provide an upconverted signal 1324. A filter 1326 filters the upconverted signal 1324 to remove undesired signals caused by the frequency up-conversion as well as noise in a receive frequency band. A power amplifier (PA) 1328 amplifies the upconverted signal 1324 from the filter 1326 to obtain the desired output power level and provides a transmit RF signal. The transmit RF signal is routed through a duplexer or switch 1330 and transmitted via an antenna 1332.

In the receive path, the antenna 1332 receives signals transmitted by base stations and provides a received RF signal, which is routed through the duplexer or switch 1330 and provided to a low noise amplifier (LNA) 1334. The duplexer or switch 1330 is designed to operate with a specific receive (RX)-to-TX duplexer frequency separation, such that RX signals are isolated from TX signals. The received RF signal is amplified by the LNA 1334 and filtered by a filter 1336 to obtain a desired RF input signal. Down-conversion mixers 1338(1), 1338(2) mix the output of the filter 1336 with I and Q RX LO signals (i.e., LO_I and LO_Q) from an RX LO signal generator 1340 to generate I and Q baseband signals. The I and Q baseband signals are amplified by AMPs 1342(1), 1342(2) and further filtered by lowpass filters 1344(1), 1344(2) to obtain I and Q analog input signals, which are provided to the data processor 1306. In this example, the data processor 1306 includes analog-to-digital converters (ADCs) 1346(1), 1346(2) for converting the analog input signals into digital signals to be further processed by the data processor 1306.

In the wireless communications device 1300 of FIG. 13, the TX LO signal generator 1322 generates the I and Q TX LO signals used for frequency up-conversion, while the RX LO signal generator 1340 generates the I and Q RX LO signals used for frequency down-conversion. Each LO signal is a periodic signal with a particular fundamental frequency. A TX phase-locked loop (PLL) circuit 1348 receives timing information from the data processor 1306 and generates a control signal used to adjust the frequency and/or phase of the TX LO signals from the TX LO signal generator 1322. Similarly, an RX PLL circuit 1350 receives timing information from the data processor 1306 and generates a control signal used to adjust the frequency and/or phase of the RX LO signals from the RX LO signal generator 1340.

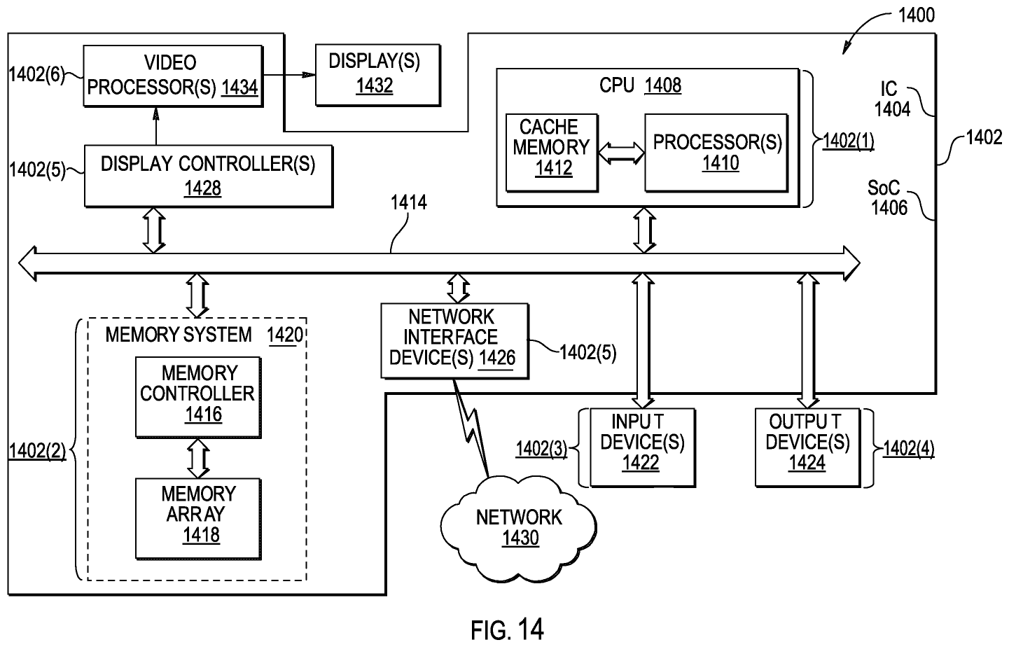

FIG. 14 illustrates an example of a processor-based system 1400 that includes circuits that can be provided in an IC package(s) that includes a die coupled to an exemplary package substrate, wherein the package substrate includes metallization layers that include an additional metal pad layer in an insulating layer of a metallization layer electrically coupling a via to a metal interconnect (e.g., an embedded metal trace) in a metal layer of the metallization layers to facilitate a reduced via size and metal interconnect size to support a reduced bump pitch in the package substrate, including, but not limited to, the package substrates in FIGS. 2A-3B, 7I, 8-9B, and 12I, and according to the exemplary fabrication processes in FIGS. 5, 6A-6D, and 11A-11C, and according to any aspects disclosed herein. Any of the IC packages 1402, 1402(1)-1402(6) can include a package substrate, wherein the package substrate includes metallization layers that include an additional metal pad layer in an insulating layer of a metallization layer electrically coupling a via to a metal interconnect (e.g., an embedded metal trace) in a metal layer of the metallization layers to facilitate a reduced via size and metal interconnect size to support a reduced bump pitch in the package substrate, including, but not limited to, the package substrates in FIGS. 2A-3B, 7I, 8-9B, and 12I, and according to the exemplary fabrication processes in FIGS. 5, 6A-6D, and 11A-11C, and according to any aspects disclosed herein.

In this example, the processor-based system 1400 may be formed as an IC 1404 in an IC package 1402 and as a system-on-a-chip (SoC) 1406. The processor-based system 1400 includes a central processing unit (CPU) 1408 that includes one or more processors 1410, which may also be referred to as CPU cores or processor cores. The CPU 1408 can be included in an IC package 1402(1). The CPU 1408 may have cache memory 1412 coupled to the CPU 1408 for rapid access to temporarily stored data. The CPU 1408 is coupled to a system bus 1414 and can intercouple master and slave devices included in the processor-based system 1400. As is well known, the CPU 1408 communicates with these other devices by exchanging address, control, and data information over the system bus 1414. For example, the CPU 1408 can communicate bus transaction requests to a memory controller 1416, as an example of a slave device. Although not illustrated in FIG. 14, multiple system buses 1414 could be provided, wherein each system bus 1414 constitutes a different fabric.

Other master and slave devices can be connected to the system bus 1414. As illustrated in FIG. 14, these devices can include a memory system 1420 that can be in a separate IC package 1402(2) and that includes the memory controller 1416 and a memory array(s) 1418, one or more input devices 1422 (that can be in a separate IC package 1402(3)), one or more output devices 1424 (that can be in a separate IC package 1402(4)), one or more network interface devices 1426, and one or more display controllers 1428 as examples. Each of the memory system 1420, the one or more input devices 1422, the one or more output devices 1424, the one or more network interface devices 1426, and the one or more display controllers 1428 can be provided in the same or different IC packages. The input device(s) 1422 can include any type of input device, including, but not limited to, input keys, switches, voice processors, etc. The output device(s) 1424 can include any type of output device, including, but not limited to, audio, video, other visual indicators, etc. The network interface device(s) 1426 can be any device configured to allow exchange of data to and from a network 1430. The network 1430 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1426 can be configured to support any type of communications protocol desired.

The CPU 1408 may also be configured to access the display controller(s) 1428 over the system bus 1414 to control information sent to one or more displays 1432. The display controller(s) 1428 sends information to the display(s) 1432 to be displayed via one or more video processors 1434, which process the information to be displayed into a format suitable for the display(s) 1432. The display controller(s) 1428 and video processor(s) 1434 can be included as ICs in the same or different IC packages 1402(5), 1402(6), or in the same or different IC package 1402, 1402(1) containing the CPU 1408, as examples. The display(s) 1432 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A package substrate, comprising:
   a first metallization layer extending in a first direction, the first metallization layer comprising:
      a first surface and a second surface opposite the first surface in a second direction orthogonal to the first direction;
      a first metal layer adjacent to the first surface, the first metal layer, comprising a plurality of first metal interconnects; and
      a first insulating layer, comprising:
         a first metal pad layer, comprising:
         a plurality of first metal pads each in contact with a first metal interconnect of the plurality of first metal interconnects; and
         a plurality of first vias adjacent to the second surface and each in contact with a first metal pad of the plurality of first metal pads.
2. The package substrate of clause 1, wherein the first metal layer is at least partially embedded in the first insulating layer, and the plurality of first metal interconnects comprises a plurality of first embedded metal traces embedded in the first insulating layer.
3. The package substrate of clause 2, further comprising:
   a second metallization layer extending in the first direction and coupled to the first metallization layer, the second metallization layer comprising:
      a third surface and a fourth surface opposite the third surface in the second direction;
      a second insulating layer;
      a second metal layer at least partially embedded in the second insulating layer and adjacent to the third surface, the second metal layer comprising a plurality of second embedded metal traces embedded in the second insulating layer; and
      the second insulating layer, comprising:
         a second metal pad layer, comprising:
         a plurality of second metal pads each in contact with a second embedded metal trace of the plurality of second embedded metal traces; and
         a plurality of second vias adjacent to the fourth surface and each in contact with a second metal pad of the plurality of second metal pads;
   wherein:
      the plurality of first vias are each coupled to a second embedded metal trace of the plurality of second embedded metal traces.
4. The package substrate of clause 1, wherein the first metal layer is coupled to the first insulating layer.
5. The package substrate of clause 4, further comprising:
   a second metallization layer extending in the first direction and comprising:
      a third surface and a fourth surface opposite the third surface in the second direction; and
      a second metal layer coupled to a second insulating layer and adjacent to the third surface, the second metal layer comprising a plurality of second metal interconnects;
      the second insulating layer, comprising:
         a plurality of second vias adjacent to the fourth surface and each in contact with a second metal interconnect of the plurality of second metal interconnects.
6. The package substrate of clause 5, further comprising a core layer between the first metallization layer and the second metallization layer in the first direction;
   the core layer comprising a plurality of third vias each coupled to a first metal interconnect of the plurality of first metal interconnects and a second metal interconnect of the plurality of second metal interconnects.
7. The package substrate of clause 4, further comprising:
   a second metallization layer extending in the first direction and comprising:
      a third surface and a fourth surface opposite the third surface in the second direction;
      a second metal layer coupled to a second insulating layer and adjacent to the third surface, the second metal layer comprising a plurality of second metal interconnects; and
      the second insulating layer, comprising:
         a second metal pad layer, comprising:
         a plurality of second metal pads each in contact with a second metal interconnect of the plurality of second metal interconnects; and
         a plurality of second vias adjacent to the fourth surface and each in contact with a second metal pad of the plurality of second metal pads.
8. The package substrate of clause 7, further comprising a core layer between the first metallization layer and the second metallization layer in the first direction;
   the core layer comprising a plurality of third vias each coupled to a first metal interconnect of the plurality of first metal interconnects and a second metal interconnect of the plurality of second metal interconnects.
9. The package substrate of any of clauses 1-8, wherein:
   the plurality of first metal interconnects has a first pitch in the first direction; and
   the plurality of first metal pads has a second pitch equal to the first pitch in the first direction.
10. The package substrate of any of clauses 1-9, wherein the plurality of first metal interconnects has a first pitch in the first direction less than or equal to one hundred (100) micrometers (μm).
11. The package substrate of any of clauses 1-9, wherein the plurality of first metal interconnects has a first pitch in the first direction less than or equal to eighty (80) micrometers (μm).
12. The package substrate of any of clauses 9-11, wherein:
   the plurality of first metal interconnects each have a first width in the first direction; and
   the plurality of first metal pads each have a second width less than the first width in the first direction.
13. The package substrate of any of clauses 1-12, wherein:
   each first metal interconnect of the plurality of first metal interconnects is separated from an adjacent first metal interconnect of the plurality of first metal interconnects by a first distance;
   each first metal pad of the plurality of first metal pads is separated from an adjacent first metal pad of the plurality of first metal pads by a second distance greater than the first distance.
14. The package substrate of any of clauses 1-13, further comprising:
   a second metallization layer extending in the first direction and coupled to the first metallization layer, the second metallization layer comprising:
      a third surface and a fourth surface opposite the third surface in the second direction;
      a second metal layer adjacent to the third surface, the second metal layer comprising a plurality of second metal interconnects; and
      a second insulating layer, comprising:
         a second metal pad layer, comprising:
         a plurality of second metal pads each in contact with a second metal interconnect of the plurality of second metal interconnects; and
         a plurality of second vias adjacent to the fourth surface and each in contact with a second metal pad of the plurality of second metal pads;
   wherein:
      the plurality of first vias are each coupled to a second metal interconnect of the plurality of second metal interconnects.
15. The package substrate of any of clauses 1-14, wherein the first metal layer further comprises one or more second metal interconnects each disposed between two (2) first metal interconnects of the plurality of first metal interconnects in the first direction.
16. The package substrate of clause 15, wherein each of the one or more second metal interconnects is not coupled to a first metal pad of the plurality of first metal pads.
17. The package substrate of any of clauses 1-16 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
18. A method of fabricating a package substrate, comprising:
forming a first metallization layer extending in a first direction, comprising:
   forming a first metal layer adjacent to a first surface;
   forming a plurality of first metal interconnects in the first metal layer;
   forming a first metal pad layer adjacent to the first metal layer;
   forming a plurality of first metal pads in the first metal pad layer and each in contact with a first metal interconnect of the plurality of first metal interconnects;
   disposing a first insulating layer on the plurality of first metal pads and the first surface adjacent to the plurality of first metal interconnects; and
   forming a plurality of first vias in the first insulating layer and each in contact with a first metal pad of the plurality of first metal pads, the plurality of first vias adjacent to a second surface opposite the first surface in a second direction orthogonal to the first direction.
19. The method of clause 18, wherein disposing the first insulating layer further comprises disposing the first insulating layer adjacent to the plurality of first metal interconnects such that the plurality of first metal interconnects comprises a plurality of embedded metal traces embedded in the first insulating layer.
20. The method of clause 18, wherein disposing the first insulating layer further comprises disposing the first insulating layer adjacent to the first metal layer.
21. The method of any of clauses 18-20, further comprising:
   forming a second metallization layer extending in the first direction, comprising:
      forming a second metal layer adjacent to a third surface;
      forming a plurality of second metal interconnects in the second metal layer;
      forming a second metal pad layer adjacent to the second metal layer;
      forming a plurality of second metal pads in the second metal pad layer and each in contact with a second metal interconnect of the plurality of second metal interconnects;
      forming a second insulating layer on the plurality of second metal pads and the third surface adjacent to the plurality of second metal interconnects; and
      forming a plurality of second vias in the second insulating layer and each in contact with a second metal pad of the plurality of second metal pads, the plurality of second vias adjacent to a fourth surface opposite the third surface in the first direction; and
   coupling the first metallization layer to the second metallization layer comprising coupling each of the plurality of first vias to a second metal interconnect of the plurality of second metal interconnects.
22. The method of any of clauses 18-21, further comprising forming one or more second metal interconnects between two (2) first metal interconnects of the plurality of first metal interconnects in the first direction; wherein each of the one or more second metal interconnects is not coupled to a first metal pad of the plurality of first metal pads.
23 The method of any of clauses 18-22, further comprising:
   forming a plurality of first openings in the first insulating layer each aligned to a first metal pad of the plurality of first metal pads; and
   filling each of the plurality of first openings with a metal material to form the plurality of first vias each in contact with the first metal pad of the plurality of first metal pads.
24. An integrated circuit (IC) package, comprising:
   a package substrate, comprising:
      a first metallization layer extending in a first direction, the first metallization layer comprising:
         a first surface and a second surface opposite the first surface in a second direction orthogonal to the first direction;
         a first metal layer adjacent to the first surface, the first metal layer comprising a plurality of first metal interconnects; and
         a first insulating layer, comprising:
         a first metal pad layer, comprising:
         a plurality of first metal pads each in contact with a first metal interconnect of the plurality of first metal interconnects; and
         a plurality of first vias adjacent to the second surface and each in contact with a first metal pad of the plurality of first metal pads; and
   a die comprising a plurality of die interconnects each coupled to a first metal interconnect of the plurality of first metal interconnects.
25. The IC package of clause 24, wherein a capacitor is coupled to at least one first metal interconnect of the plurality of first metal interconnects.
26. The IC package of clause 25, wherein the capacitor is coupled to the at least one first metal interconnect by the capacitor being coupled to at least one first via of the plurality of first vias.
27. The IC package of any of clauses 24-26, wherein the first metal layer is at least partially embedded in the first insulating layer, and the plurality of first metal interconnects comprises a plurality of first embedded metal traces embedded in the first insulating layer.
28. The IC package of clause 27, wherein the package substrate further comprises:
   a second metallization layer extending in the first direction and coupled to the first metallization layer, the second metallization layer comprising:
      a third surface and a fourth surface opposite the third surface in the second direction;
      a second insulating layer;
      a second metal layer at least partially embedded in the second insulating layer and adjacent to the third surface, the second metal layer comprising a plurality of second embedded metal traces embedded in the second insulating layer; and
      the second insulating layer, comprising:
         a second metal pad layer, comprising:
         a plurality of second metal pads each in contact with a second embedded metal trace of the plurality of second embedded metal traces; and
         a plurality of second vias adjacent to the fourth surface and each in contact with a second metal pad of the plurality of second metal pads;
wherein:
   the plurality of first vias are each coupled to a second embedded metal trace of the plurality of second embedded metal traces.
29. The IC package of any of clauses 24-26, wherein the first metal layer is coupled to the first insulating layer.
30. The IC package of clause 29, wherein the package substrate further comprises:
   a second metallization layer extending in the first direction and comprising:
      a third surface and a fourth surface opposite the third surface in the second direction; and
      a second metal layer coupled to a second insulating layer and adjacent to the third surface, the second metal layer comprising a plurality of second metal interconnects;
      the second insulating layer, comprising:
         a plurality of second vias adjacent to the fourth surface and each in contact with a second metal interconnect of the plurality of second metal interconnects.

What is claimed is:

1. A package substrate, comprising:
a first metallization layer extending in a first direction, the first metallization layer comprising:
a first surface and a second surface opposite the first surface in a second direction orthogonal to the first direction;
a first metal layer adjacent to the first surface, the first metal layer, comprising a plurality of first metal interconnects; and
a first insulating layer, comprising:
a first metal pad layer, comprising:
a plurality of first metal pads each in contact with a first metal interconnect of the plurality of first metal interconnects; and
a plurality of first vias adjacent to the second surface and each in contact with a first metal pad of the plurality of first metal pads.

2. The package substrate of claim 1, wherein the first metal layer is at least partially embedded in the first insulating layer, and the plurality of first metal interconnects comprises a plurality of first embedded metal traces embedded in the first insulating layer.

3. The package substrate of claim 2, further comprising:
a second metallization layer extending in the first direction and coupled to the first metallization layer, the second metallization layer comprising:
a third surface and a fourth surface opposite the third surface in the second direction;
a second insulating layer;
a second metal layer at least partially embedded in the second insulating layer and adjacent to the third surface, the second metal layer comprising a plurality of second embedded metal traces embedded in the second insulating layer; and
the second insulating layer, comprising:
a second metal pad layer, comprising:
a plurality of second metal pads each in contact with a second embedded metal trace of the plurality of second embedded metal traces; and
a plurality of second vias adjacent to the fourth surface and each in contact with a second metal pad of the plurality of second metal pads;
wherein:
the plurality of first vias are each coupled to a second embedded metal trace of the plurality of second embedded metal traces.

4. The package substrate of claim 1, wherein the first metal layer is coupled to the first insulating layer.

5. The package substrate of claim 4, further comprising:
a second metallization layer extending in the first direction and comprising:
a third surface and a fourth surface opposite the third surface in the second direction; and
a second metal layer coupled to a second insulating layer and adjacent to the third surface, the second metal layer comprising a plurality of second metal interconnects;
the second insulating layer, comprising:
a plurality of second vias adjacent to the fourth surface and each in contact with a second metal interconnect of the plurality of second metal interconnects.

6. The package substrate of claim 5, further comprising a core layer between the first metallization layer and the second metallization layer in the first direction;
the core layer comprising a plurality of third vias each coupled to a first metal interconnect of the plurality of first metal interconnects and a second metal interconnect of the plurality of second metal interconnects.

7. The package substrate of claim 4, further comprising:
a second metallization layer extending in the first direction and comprising:
a third surface and a fourth surface opposite the third surface in the second direction;
a second metal layer coupled to a second insulating layer and adjacent to the third surface, the second metal layer comprising a plurality of second metal interconnects; and
the second insulating layer, comprising:
a second metal pad layer, comprising:
a plurality of second metal pads each in contact with a second metal interconnect of the plurality of second metal interconnects; and
a plurality of second vias adjacent to the fourth surface and each in contact with a second metal pad of the plurality of second metal pads.

8. The package substrate of claim 7, further comprising a core layer between the first metallization layer and the second metallization layer in the first direction;
the core layer comprising a plurality of third vias each coupled to a first metal interconnect of the plurality of first metal interconnects and a second metal interconnect of the plurality of second metal interconnects.

9. The package substrate of claim 1, wherein:
the plurality of first metal interconnects has a first pitch in the first direction; and
the plurality of first metal pads has a second pitch equal to the first pitch in the first direction.

10. The package substrate of claim 1, wherein the plurality of first metal interconnects has a first pitch in the first direction less than or equal to one hundred (100) micrometers (μm).

11. The package substrate of claim 1, wherein the plurality of first metal interconnects has a first pitch in the first direction less than or equal to eighty (80) micrometers (μm).

12. The package substrate of claim 9, wherein:
the plurality of first metal interconnects each have a first width in the first direction; and
the plurality of first metal pads each have a second width less than the first width in the first direction.

13. The package substrate of claim 1, wherein:
each first metal interconnect of the plurality of first metal interconnects is separated from an adjacent first metal interconnect of the plurality of first metal interconnects by a first distance;
each first metal pad of the plurality of first metal pads is separated from an adjacent first metal pad of the plurality of first metal pads by a second distance greater than the first distance.

14. The package substrate of claim 1, further comprising:
a second metallization layer extending in the first direction and coupled to the first metallization layer, the second metallization layer comprising:
a third surface and a fourth surface opposite the third surface in the second direction;
a second metal layer adjacent to the third surface, the second metal layer comprising a plurality of second metal interconnects; and
a second insulating layer, comprising:
a second metal pad layer, comprising:
a plurality of second metal pads each in contact with a second metal interconnect of the plurality of second metal interconnects; and
a plurality of second vias adjacent to the fourth surface and each in contact with a second metal pad of the plurality of second metal pads;
wherein:
the plurality of first vias are each coupled to a second metal interconnect of the plurality of second metal interconnects.

15. The package substrate of claim 1, wherein the first metal layer further comprises one or more second metal interconnects each disposed between two (2) first metal interconnects of the plurality of first metal interconnects in the first direction.

16. The package substrate of claim 15, wherein each of the one or more second metal interconnects is not coupled to a first metal pad of the plurality of first metal pads.

17. The package substrate of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

18. A method of fabricating a package substrate, comprising:
forming a first metallization layer extending in a first direction, comprising:
forming a first metal layer adjacent to a first surface;
forming a plurality of first metal interconnects in the first metal layer;
forming a first metal pad layer adjacent to the first metal layer;
forming a plurality of first metal pads in the first metal pad layer and each in contact with a first metal interconnect of the plurality of first metal interconnects;
disposing a first insulating layer on the plurality of first metal pads and the first surface adjacent to the plurality of first metal interconnects; and
forming a plurality of first vias in the first insulating layer and each in contact with a first metal pad of the plurality of first metal pads, the plurality of first vias adjacent to a second surface opposite the first surface in a second direction orthogonal to the first direction.

19. The method of claim 18, wherein disposing the first insulating layer further comprises disposing the first insulating layer adjacent to the plurality of first metal interconnects such that the plurality of first metal interconnects comprises a plurality of embedded metal traces embedded in the first insulating layer.

20. The method of claim 18, wherein disposing the first insulating layer further comprises disposing the first insulating layer adjacent to the first metal layer.

21. The method of claim 18, further comprising:
forming a second metallization layer extending in the first direction, comprising:
forming a second metal layer adjacent to a third surface;
forming a plurality of second metal interconnects in the second metal layer;
forming a second metal pad layer adjacent to the second metal layer;
forming a plurality of second metal pads in the second metal pad layer and each in contact with a second metal interconnect of the plurality of second metal interconnects;
forming a second insulating layer on the plurality of second metal pads and the third surface adjacent to the plurality of second metal interconnects; and
forming a plurality of second vias in the second insulating layer and each in contact with a second metal pad of the plurality of second metal pads, the plurality of second vias adjacent to a fourth surface opposite the third surface in the first direction; and
coupling the first metallization layer to the second metallization layer comprising coupling each of the plurality of first vias to a second metal interconnect of the plurality of second metal interconnects.

22. The method of claim 18, further comprising forming one or more second metal interconnects between two (2) first metal interconnects of the plurality of first metal interconnects in the first direction; wherein each of the one or more second metal interconnects is not coupled to a first metal pad of the plurality of first metal pads.

23. The method of claim 18, further comprising:
forming a plurality of first openings in the first insulating layer each aligned to a first metal pad of the plurality of first metal pads; and
filling each of the plurality of first openings with a metal material to form the plurality of first vias each in contact with the first metal pad of the plurality of first metal pads.

24. An integrated circuit (IC) package, comprising:
a package substrate, comprising:
a first metallization layer extending in a first direction, the first metallization layer comprising:
a first surface and a second surface opposite the first surface in a second direction orthogonal to the first direction;
a first metal layer adjacent to the first surface, the first metal layer comprising a plurality of first metal interconnects; and
a first insulating layer, comprising:
a first metal pad layer, comprising:
a plurality of first metal pads each in contact with a first metal interconnect of the plurality of first metal interconnects; and
a plurality of first vias adjacent to the second surface and each in contact with a first metal pad of the plurality of first metal pads; and
a die comprising a plurality of die interconnects each coupled to a first metal interconnect of the plurality of first metal interconnects.

25. The IC package of claim 24, wherein a capacitor is coupled to at least one first metal interconnect of the plurality of first metal interconnects.

26. The IC package of claim 25, wherein the capacitor is coupled to the at least one first metal interconnect by the capacitor being coupled to at least one first via of the plurality of first vias.

27. The IC package of claim 24, wherein the first metal layer is at least partially embedded in the first insulating layer, and the plurality of first metal interconnects comprises a plurality of first embedded metal traces embedded in the first insulating layer.

28. The IC package of claim 27, wherein the package substrate further comprises:
a second metallization layer extending in the first direction and coupled to the first metallization layer, the second metallization layer comprising:
a third surface and a fourth surface opposite the third surface in the second direction;
a second insulating layer;
a second metal layer at least partially embedded in the second insulating layer and adjacent to the third surface, the second metal layer comprising a plurality of second embedded metal traces embedded in the second insulating layer; and
the second insulating layer, comprising:
a second metal pad layer, comprising:
a plurality of second metal pads each in contact with a second embedded metal trace of the plurality of second embedded metal traces; and
a plurality of second vias adjacent to the fourth surface and each in contact with a second metal pad of the plurality of second metal pads;
wherein:
the plurality of first vias are each coupled to a second embedded metal trace of the plurality of second embedded metal traces.

29. The IC package of claim 24, wherein the first metal layer is coupled to the first insulating layer.

30. The IC package of claim 29, wherein the package substrate further comprises:
a second metallization layer extending in the first direction and comprising:
a third surface and a fourth surface opposite the third surface in the second direction; and
a second metal layer coupled to a second insulating layer and adjacent to the third surface, the second metal layer comprising a plurality of second metal interconnects;
the second insulating layer, comprising:
a plurality of second vias adjacent to the fourth surface and each in contact with a second metal interconnect of the plurality of second metal interconnects.
